(19) United States
(12) Patent Application Publication
(10) Pub. No.: US 2013/0175654 A1
(43) Pub. Date: Jul. 11, 2013

(54) BULK NANOHOLE STRUCTURES FOR THERMOELECTRIC DEVICES AND METHODS FOR MAKING THE SAME

(71) Applicants: Sylvain Muckenhirn, Santa Barbara, CA (US); Chii Guang Lee, Fremont, CA (US); Matthew L. Scullin, San Francisco, CA (US)

(72) Inventors: Sylvain Muckenhirn, Santa Barbara, CA (US); Chii Guang Lee, Fremont, CA (US); Matthew L. Scullin, San Francisco, CA (US)

(21) Appl. No.: 13/760,977

(22) Filed: Feb. 6, 2013

Related U.S. Application Data
(60) Provisional application No. 61/597,254, filed on Feb. 10, 2012.

(51) Int. Cl. H01L 29/06; H01L 21/308; H01L 21/768; H01L 35/04

(52) U.S. Cl. CPC H01L 29/0665; H01L 35/04; H01L 21/308; H01L 21/76802
USPC 257/467; 257/618; 438/694; 438/674

(57) ABSTRACT

Array of nanoholes and method for making the same. The array of nanoholes includes a plurality of nanoholes. Each of the plurality of nanoholes corresponds to a first end and a second end, and the first end and the second end are separated by a first distance of at least 100 μm. Each of the plurality of nanoholes corresponds to a cross-sectional area associated with a distance across, and the distance across ranges from 5 nm to 500 nm. Each of the plurality of nanoholes is separated from at least another nanohole selected from the plurality of nanoholes by a semiconductor material associated with a sidewall thickness, and the sidewall thickness ranges from 5 nm to 500 nm.

### 1. CROSS-REFERENCES TO RELATED APPLICATIONS

This application claims priority to U.S. Provisional Application No. 61/597,254, filed Feb. 10, 2012, commonly assigned and incorporated by reference herein for all purposes.

### 2. BACKGROUND OF THE INVENTION

The present invention is directed to nanostructures. More particularly, the invention provides bulk nanohole structures. Merely by way of example, the invention has been applied to thermoelectric devices. However, it would be recognized that the invention has a much broader range of applicability, including but not limited to use in transistor, solar power converter, battery electrodes and/or energy storage, catalysis, and/or light emitting diodes.

Nanohole and nanomesh devices have been shown to have good thermoelectric figures of merit ZT. ZT=S²σ/k, where S is the material's thermopower, σ is the electrical conductivity, and k is the thermal conductivity. These devices have been formed in thin silicon-on-insulator epitaxial layers or formed from arrays of nanowires, and result in nanoscale structures in thin films that are very small in physical size. For example, some conventional silicon nanoholes have been fabricated from a thin silicon film of 10-1000 nm within a conventional silicon wafer, whereby the remainder of the silicon wafer that is about 500 μm thick is etched and discarded. In another example, the resulting conventional structures are thin films and resemble ribbons, which have been shown to be microns wide and microns long, tens to hundreds of nanometers thick, with 1-100 nm diameter holes within. These conventional structures demonstrate the ability of closely-packed nanostructures to affect phonon thermal transport by reducing thermal conductivity while not affecting electrical properties greatly, thereby improving thermoelectric efficiency ZT.

Hence, it is highly desirable to improve techniques of nanohole devices.

### 3. BRIEF SUMMARY OF THE INVENTION

The present invention is directed to nanostructures. More particularly, the invention provides bulk nanohole structures. Merely by way of example, the invention has been applied to thermoelectric devices. However, it would be recognized that the invention has a much broader range of applicability, including but not limited to use in transistor, solar power converter, battery electrodes and/or energy storage, catalysis, and/or light emitting diodes.

According to one embodiment, an array of nanoholes includes a plurality of nanoholes. Each of the plurality of nanoholes corresponds to a first end and a second end, and the first end and the second end are separated by a first distance of at least 100 μm. Each of the plurality of nanoholes corresponds to a cross-sectional area associated with a distance across, and the distance across ranges from 5 nm to 500 nm. Each of the plurality of nanoholes is separated from at least another nanohole selected from the plurality of nanoholes by a semiconductor material associated with a sidewall thickness, and the sidewall thickness ranges from 5 nm to 500 nm.

According to another embodiment, a structure including an array of nanoholes includes a semiconductor substrate with a plurality of nanoholes. The semiconductor substrate includes a first surface, a second surface opposite to the first surface, a third surface extending from the first surface towards the second surface, and a fourth surface extending from the first surface towards the second surface. Each of the plurality of nanoholes corresponds to a first end at the first surface and a second end. Additionally, the structure includes a first thermal and electrical contact material coupled to the third surface, and a second thermal and electrical contact material coupled to the fourth surface. Each of the plurality of nanoholes corresponds to a cross-sectional area associated with a distance across, and the distance across ranges from 5 nm to 500 nm. Each of the plurality of nanoholes is separated from at least another nanohole selected from the plurality of nanoholes by a semiconductor sidewall associated with a sidewall thickness. The semiconductor sidewall is a part of the semiconductor substrate, and the sidewall thickness ranges from 5 nm to 500 nm.

According to yet another embodiment, a method for forming an array of nanoholes includes providing a semiconductor substrate including a first surface and forming a mask on the first surface. The mask includes mask regions separated by corresponding mask holes, and portions of the first surface are exposed within the corresponding mask holes. Additionally, the method includes etching the semiconductor substrate through at least the exposed portion of the first surface to form at least nanoholes. Each of the nanoholes corresponds to a first end and a second end, and the first end and the second end are separated by a first distance of at least 100 μm. Each of the nanoholes corresponds to a cross-sectional area associated with a distance across ranging from 5 nm to 500 nm. Each of the nanoholes is separated from at least another of the nanoholes by a semiconductor sidewall associated with a sidewall thickness ranging from 5 nm to 500 nm, and the semiconductor sidewall is a part of the semiconductor substrate.

According to yet another embodiment, a method for forming a structure including an array of nanoholes includes providing a semiconductor substrate including a first surface and forming a mask on the first surface. The mask includes mask regions separated by corresponding mask holes, and portions of the first surface are exposed within the corresponding mask holes. Additionally, the method includes etching the semiconductor substrate through at least the exposed portion of the first surface to form at least nanoholes. Each of the nanoholes corresponds to a first end at the first surface and a second end. Each of the nanoholes corresponding to a cross-sectional area associated with a distance across ranging from 5 nm to 500 nm. Each of the nanoholes is separated from at least another of the nanoholes by a semiconductor sidewall associated with a sidewall thickness ranging from 5 nm to 500 nm, and the semiconductor sidewall is a part of the semiconductor substrate. Also, the method includes etching the semiconductor substrate to form at least a first trench and a second trench, forming a first thermal and electrical contact within the first trench with the semiconductor substrate, and forming a second thermal and electrical contact within the second trench with the semiconductor substrate.

Depending upon the embodiment, one or more benefits may be achieved. These benefits and various additional objects, features, and advantages of the present invention can be fully appreciated with reference to the detailed description and accompanying drawings that follow.

### 4. BRIEF DESCRIPTION OF THE DRAWINGS

FIGS. 1A-1D are simplified diagrams showing a method for making one or more arrays of nanoholes in a substrate according to an embodiment of the present invention.

FIG. 2 is a simplified diagram showing a top view of the array of nanoholes as shown in FIG. 1C and/or the array of nanoholes as shown in FIG. 1D according to certain embodiments of the present invention.

FIG. 3A is a simplified diagram showing a top view of a substrate for making one or more arrays of nanoholes in the substrate according to an embodiment of the present invention.

FIG. 3B is a simplified diagram showing a side view of a patch of the substrate for making one or more arrays of nanoholes in the substrate according to an embodiment of the present invention.

FIG. 3C is a simplified diagram showing a side view of a stripe of the substrate for making one or more arrays of nanoholes in the substrate according to another embodiment of the present invention.

FIGS. 4A-4H are simplified diagrams showing a method for making one or more arrays of nanoholes in a substrate according to another embodiment of the present invention.

FIG. 5A is a simplified diagram showing a top view of the structure as shown in FIG. 4H according to one embodiment of the present invention.

FIG. 5B is a simplified diagram showing a top view of a structure that includes multiple structures as shown in FIG. 4H according to another embodiment of the present invention.

FIGS. 6A-6P are simplified diagrams showing a method for making one or more arrays of nanoholes in a substrate according to yet another embodiment of the present invention.

FIGS. 7A-7E are simplified diagrams showing a method for making one or more arrays of nanoholes in a substrate according to yet another embodiment of the present invention.

### 5. DETAILED DESCRIPTION OF THE INVENTION

The present invention is directed to nanostructures. More particularly, the invention provides bulk nanohole structures. Merely by way of example, the invention has been applied to thermoelectric devices. However, it would be recognized that the invention has a much broader range of applicability, including but not limited to use in transistor, solar power converter, battery electrodes and/or energy storage, catalysis, and/or light emitting diodes.

To improve techniques of nanohole devices, it is of interest to transform nanohole structures into bulk electronic devices. These devices may be transistors, thermoelectrics, or other electronic devices. For example, a bulk nanohole thermoelectric device used for power generation should transport a significant amount of electric current from one electrode to another, where a temperature gradient is applied to the thermoelectric material and the Seebeck effect is employed to generate a gradient in voltage and in turn the flow of electrical current. In another example, a bulk nanohole thermoelectric device used for refrigeration should carry an appreciable amount of heat with an applied electric current by way of the Peltier effect. In both of these configurations for thermoelectric devices, ZT of the thermoelectric material is one indicator of the material's efficiency in either converting heat to electricity (e.g., thermopower) or pumping heat with electricity.

In certain embodiments, in a bulk nanohole thermoelectric device, electrodes should be placed on either ends of the thermoelectric material in order to collect a current from the thermoelectric material or transmit a current through the thermoelectric material. For example, these electrodes should be made such that the electrodes make low resistance electrical and thermal contact to the thermoelectric material with high ZT, and furthermore allow each thermoelectric unit of p-type or n-type semiconductor thermoelectric material (e.g., each thermoelectric leg) to be wired together with one or more other thermoelectric units and/or the external circuitry.

In some embodiments, the interesting applications for bulk nanohole thermoelectric device include heat energy scavenging for powering sensors, Peltier cooling of electronics hot-spots, and waste-heat recovery from exhaust and other heat sources, among others. According to one embodiment, in order for a bulk nanohole thermoelectric device to be usefully applied to one or more of these applications, as an example, not only should suitable electrodes be made on the thermoelectric material, but an appreciable amount of the thermoelectric material itself should be fabricated to meet the geometrical and electrical specifications of the application. According to another embodiment, in thermoelectric power generation from a heat source using the Seebeck effect, enough volume of thermoelectric material should be present between a hot-junction and a cold junction (e.g., in a counter-flow gas phase heat exchanger) so as to allow both an appreciable temperature gradient to evolve across thermoelectric legs and to allow enough current to be carried due to the temperature-induced voltage.

In more detail, a thermoelectric material fabricated with small outer dimensions, such as the conventional structures demonstrated incorporating nanoholes with relative short lengths, usually suffer from very high current densities that may preclude their use in a thermoelectric application. Furthermore, such thermoelectric structure often may not generate sufficient power or heat pumping that is applicable or cost-effective. Hence, the ability to process nanostructures for making high-performance thermoelectric devices would have signification cost advantages, if the nanostructures are fabricated with methods that are compatible with the processing of silicon and other semiconductor wafers, according to some embodiments.

For example, one may consider a thin-film thermoelectric material whose dimensions laterally in the x-y plane (e.g., in the plane of a semiconductor wafer) are on the order of hundreds of microns to millimeters, and whose dimensions vertically (e.g., cross the plane of a semiconductor wafer) are only 10-1000 nm. In another example, the thermoelectric generation power density, δ, of such a device in a load-matched condition, where the temperature gradient is applied in the z direction, is:

$$δ = \frac{{I}^{2} R}{A} = \frac{{V}^{2}}{( {R}_{internal} + {R}_{load} ) \times ( {L}_{x} \times {L}_{y} )} = \frac{{V}^{2}}{2 ρ \times {L}_{z}} \qquad ( Equation 1 )$$

where I is the current in the sample-load circuit, Rᵢₙₜₑᵣₙₐₗ is the internal resistance of the thermoelectric material, R_{load} is the resistance of the load, R is the sum of Rᵢₙₜₑᵣₙₐₗ and R_{load}. Additionally, A is the x-y cross-sectional area of the thermoelectric material that is orthogonal to the temperature gradient applied in the z direction, V is the voltage generated by the thermoelectric material, and ρ is the electrical resistivity of the thermoelectric material. Moreover, Lₓ, L_{y}, and L_{z} are the sample dimensions in the x, y, and z directions respectively.

As shown in Equation 1, for per unit area of power-generation thermoelectric material sample, the thermoelectric power can increase if the voltage generated by the sample is larger or if the electrical resistance of the sample is lower according to one embodiment. For example, the voltage generated by the sample can be increased by selecting a thermoelectric material with a larger Seebeck coefficient S (e.g., S is equal to dV/dT). In another example, the electrical resistance of the sample can be lowered by decreasing the sample length L_{z} along the axis of the temperature gradient and/or selecting a thermoelectric material with lower resistivity.

According to another embodiment, the total amount of power P produced by the thermoelectric material sample, rather than the power density, is then:

$$P = \frac{{V}^{2} \times ( {L}_{x} \times {L}_{y} )}{2 ρ \times {L}_{z}} \qquad ( Equation 2 )$$

As shown in Equation 2, for example, the thermoelectric sample that is larger in lateral x and y dimensions can produce more power, because there would be more thermoelectric material participating in the generation of voltage from an applied temperature gradient, and therefore more current generated. In another example, the thermoelectric power generation becomes problematic if a thermoelectric device is made from a thin thermoelectric film where the direction of thermal and electrical transport is in the x-y plane of the thin film, and not in the z direction.

For a conventional thermoelectric thin film with nanoholes within it, the temperature gradient often needs to be applied in a direction that is orthogonal to the z direction of the thin film so as to take advantage of the beneficial effects of the nanohole structure within the material. But, in such an arrangement, a very small amount of thermoelectric material usually can contribute to the thermoelectric conversion. For example, if the temperature gradient is applied in the y direction, referring to Equation 2, the transverse area (e.g., the cross-sectional area that is exposed to a temperature gradient through which a current may flow) is no longer Lₓ×L_{y}, but instead is equal to Lₓ×L_{z} where z is the cross-plane direction (e.g., thickness direction) of the thin film. If the z height of the thin film is only about 100 nm and the lateral dimensions are as large as several millimeters, the thermoelectric conversion would be significantly restricted in terms of the amount of electric power it can generate according to one embodiment. In another embodiment, since P is linearly proportional to the transverse area, going from a thin film thicknesses of 100 nm to greater than 100 μm would increase power generation by about 1000 times.

Therefore, when fabricating thermoelectric nanostructures from a finite wafer of material or the like, it is desirable to transform as much of the starting wafer material as possible into the thermoelectric nanostructures according to some embodiments. For example, since the commercial performance, and thus usefulness, of a power generation thermoelectric device is governed by its cost-per-Watt, it is beneficial to process a piece of material in such a fashion that maximizes its use as a thermoelectric material, because most of the two-dimensional semiconductor fabrication processes or the like usually cost about the same amount regardless of the thickness of the material being processed.

Specifically, some conventional silicon nanoholes have been fabricated from a thin silicon film of 10-1000 nm within a conventional silicon wafer, whereby the remainder of the silicon wafer that is about 500 μm thick is etched and discarded. As an example, such a resulting nanohole thermoelectric structure can possibly generate only about 1 watt of power per 8-inch silicon wafer in a temperature gradient of about 250 K. In another example, if a nanohole thermoelectric structure is made to utilize the entire thickness of the 500 μm wafer, the thermoelectric structure can increase the power generation by 500-50,000 times, or would generate 500-50,000 watts of power per wafer. In yet another example, at typical fabrication costs in semiconductor IC, MEMS, or PV processing of $5-$1,000 per wafer, using only a thin film of a silicon wafer to make a nanohole structure can be prohibitively expensive for power generation, but in contrast, using the entire wafer thickness to make a nanohole structure can result in costs-per-watt of $0.50 or less that is needed for commercial adoption according to some embodiments.

According to certain embodiment, it is therefore important to utilize far greater thicknesses of thermoelectric material than conventional technology in order to achieve significant commercial applicability. For example, it is highly desirable to improve techniques for the formation of very large or bulk nanohole structures comprising arrays of ultra-long nanoholes in a silicon wafer or other semiconductor materials (e.g., semiconductor materials that are less expensive and/or less toxic). In another example, it is also highly desirable to transform these bulk nanohole structures into thermoelectric legs by forming corresponding conductive patches at two sides of each array of ultra-long nanohole structures.

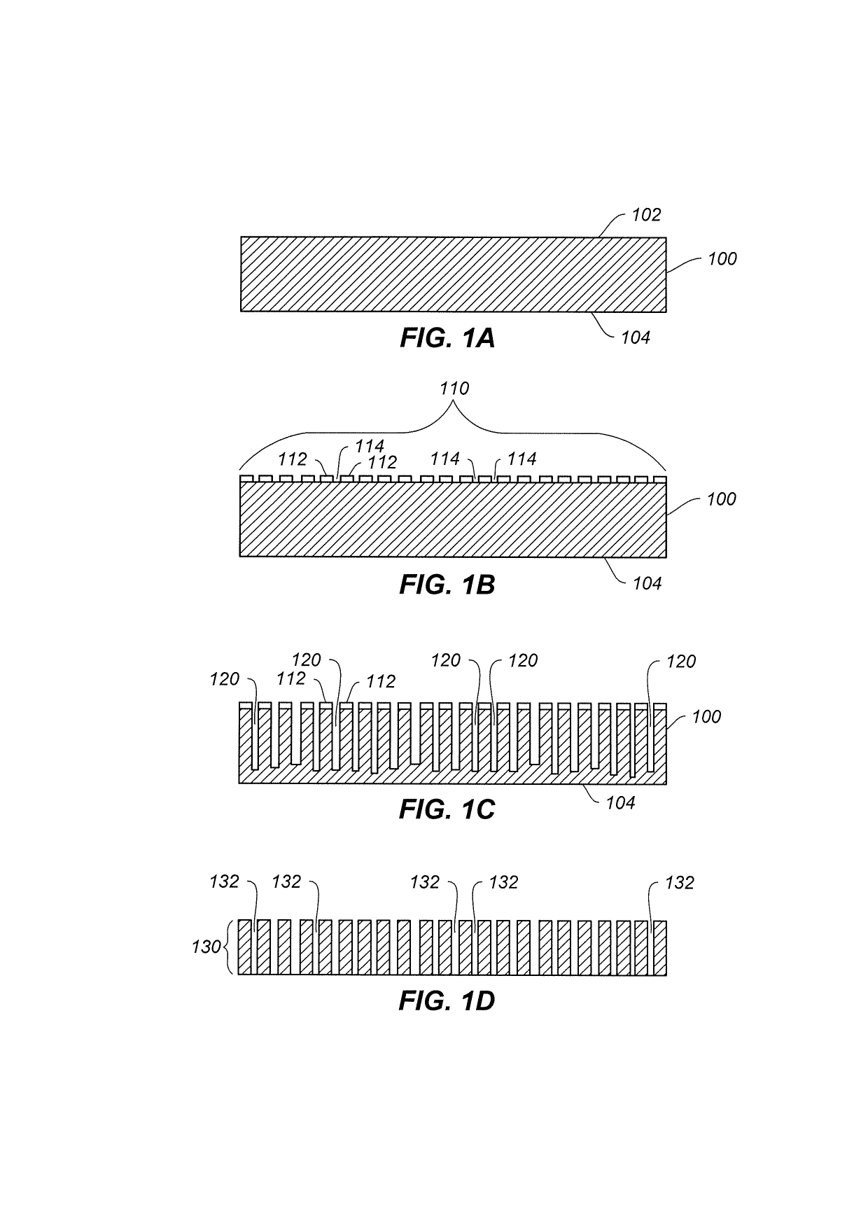

FIGS. 1A-1D are simplified diagrams showing a method for making one or more arrays of nanoholes in a substrate according to an embodiment of the present invention. These diagrams are merely examples, which should not unduly limit the scope of the claims. One of ordinary skill in the art would recognize many variations, alternatives, and modifications.

In one embodiment, the method for making one or more arrays of nanoholes in a substrate includes the following sequential processes (a) through (d):
(a) providing a substrate for forming one or more arrays of nanoholes (e.g., as shown in FIG. 1A);
(b) forming a mask on the substrate surface of the substrate (e.g., as shown in FIG. 1B);
(c) forming multiple holes in the substrate (e.g., as shown in FIG. 1C); and
(d) forming a structure with one more arrays of nanoholes (e.g., as shown in FIG. 1D).
   The method described above is merely an example, which should not unduly limit the scope of the claims. One of ordinary skill in the art would recognize many variations, alternatives, and modifications. For example, one or more of the above listed processes are skipped. In another example, the above listed processes are performed in a different order. In yet another example, one or more additional processes are added.

As shown in FIG. 1A, a substrate 100 is provided for forming one or more arrays of nanoholes. For example, the substrate 100 includes substrate surfaces 102 and 104, and the substrate surface 104 is located opposite to the substrate surface 102. In another example, the substrate 100 is selected from various types of materials depending on embodiments. In one embodiment, a semiconductor substrate is selected as the substrate 100 for making one or more thermoelectric devices. For example, the substrate 100 is a silicon substrate (e.g., a single-crystal silicon substrate). In another example, the silicon substrate is a silicon wafer without special treatment (e.g., not a silicon-on-insulator wafer). In yet another example, the silicon substrate is uniformly doped into an n-type semiconductor or a p-type semiconductor. In yet another example, the silicon substrate is pattern-doped so that the n-type doping and the p-type doping are performed alternately in alternate patches respectively across the wafer.

As shown in FIG. 1B, a mask 110 is formed on the substrate surface 102 of the substrate 100. For example, the mask 110 includes multiple mask islands 112 separated by multiple holes 114. In another example, within each hole 114, the substrate surface 102 is exposed. In yet another example, the holes 114 are in nanoscopic scale, and the hole-to-hole separations (e.g., the pitch sizes) are also in nanoscopic scale. In one embodiment, one or more co-polymer materials including metal particles are used to form the mask 110. In another embodiment, one or more photoresist materials are used to pattern another inorganic material layer in order to form the mask 110.

As shown in FIG. 1C, multiple nanoholes 120 are formed in the substrate 100. In one embodiment, the nanoholes 120 are formed by applying an etching process (e.g., an anisotropic dry etching process, an anisotropic wet etching process with an etchant solution) through the holes 114. In another embodiment, the nanoholes 120 are substantially vertical to the substrate surface 102, extending into the substrate 100 with corresponding depths. For example, the corresponding depths each exceed 100 μm. In another example, the corresponding depths each are at least 200 μm. In yet another example, the corresponding depths each are at least 400 μm. In yet another example, the corresponding depths each are at least 500 μm. In yet another example, the corresponding depths each are up to the total thickness of the substrate 100.

In yet another embodiment, the nanoholes 120 form an array of nanoholes 120. For example, the density of the array of nanoholes 120 has a hole density characterized by separations of the holes 114 (e.g., the pitch sizes). For example, the average pitch size is about 70 nm. In another example, the cross-sectional areas of corresponding nanoholes 120 determine the porosity of the resulting substrate structure as shown in FIG. 1C. In another example, the mask 110 can be applied over any bulk-like thickness dimension so that the array of nanoholes 120 can be formed across the surface regions with the same bulk-like thickness dimension.

According to some embodiments, the anisotropic wet etching process can create roughened and/or porous sidewall surfaces for the nanoholes 120 and therefore reduce the thermal conductivity. According to certain embodiments, the nanoholes 120 are formed by applying an anisotropic etching process with an etchant solution that includes HF, AgNO₃, and H₂O. For example, the molar concentration of HF in the etchant solution varies from 2M to 10M. In another example, the molar concentration of AgNO₃ in the etchant solution varies from 0.001M to 0.5M. In yet another example, other molar concentrations vary depending on the etching parameters desired. In yet another embodiment, KNO₃ is added to the etchant solution. In one example, the KNO₃ is added to the etchant solution after a certain time period of initial etching without KNO₃ in the etchant solution. In another example, KNO₃ is added to the etchant solution all at once. In yet another example, KNO₃ is added to the etchant solution continuously at a predetermined rate. In yet another example, KNO₃ is added to the etchant solution to maintain the proper balance between Ag and Ag+ to control the etching rate, the anisotropy, and/or other etch characteristics. In yet another embodiment, other oxidizing agents other than KNO₃ are added to the etchant solution. In yet another embodiment, the anisotropic etching process of the substrate 100 includes multiple subprocesses. In one example, a first etchant solution including HF, AgNO₃, and H₂O is used for a first time period and then a second etchant solution including HF, H₂O₂, and H₂O is used for a second time period. In another example, a third etchant solution including HF, AgNO₃, and H₂O is used for a third time period and then a fourth etchant solution including HF, Fe(NO₃)₃, and H₂O is used for a fourth time period. According to some embodiments, the anisotropic dry etching process is a plasma dry etching process.

As shown in FIG. 1D, a structure 130 with one or more arrays of nanoholes 132 is formed. In one embodiment, after the formation of the array of nanoholes 120, another side of the substrate 100 is polished starting from the substrate surface 104 in order to form the structure 130 with the array of nanoholes 132. For example, the nanoholes 132 are parallel with each other (e.g., being vertically-aligned nanoholes). In another example, the nanoholes 132 are either the same as the corresponding nanoholes 120 or shorter than the corresponding nanoholes 120, respectively. In yet another example, each of the nanoholes 132 has a depth that is larger than 100 μm. In yet another example, each of the nanoholes 132 has a depth that is larger than 200 μm. In yet another example, each of the nanoholes 132 has a depth that is larger than 400 μm. In yet another example, each of the nanoholes 132 has a depth that is larger than 500 μm.

In another embodiment, the cross-section of the structure 130 (e.g., the cross-section perpendicular to the vertical depth direction) can be in millimeters, centimeters, or as large as the whole substrate size. For example, the structure 130 is a bulk nanohole structure. In another example, by adjusting the masking process as shown in FIG. 1B and/or the etching process as shown in FIG. 1C, the array of nanoholes 132 for the structure 130 can correspond to different densities and/or different porosities. In yet another embodiment, the structure 130 includes a stand-alone array of nanoholes 132.

As discussed above and further emphasized here, FIGS. 1A-1D are merely examples, which should not unduly limit the scope of the claims. One of ordinary skill in the art would recognize many variations, alternatives, and modifications. For example, the process for forming a structure with an array of nanoholes (e.g., as shown in FIG. 1D) is skipped. In another example, the structure including the array of nanoholes 120 is a bulk nanohole structure. In yet another example, the structure 130 is further processed to form an electronic device.

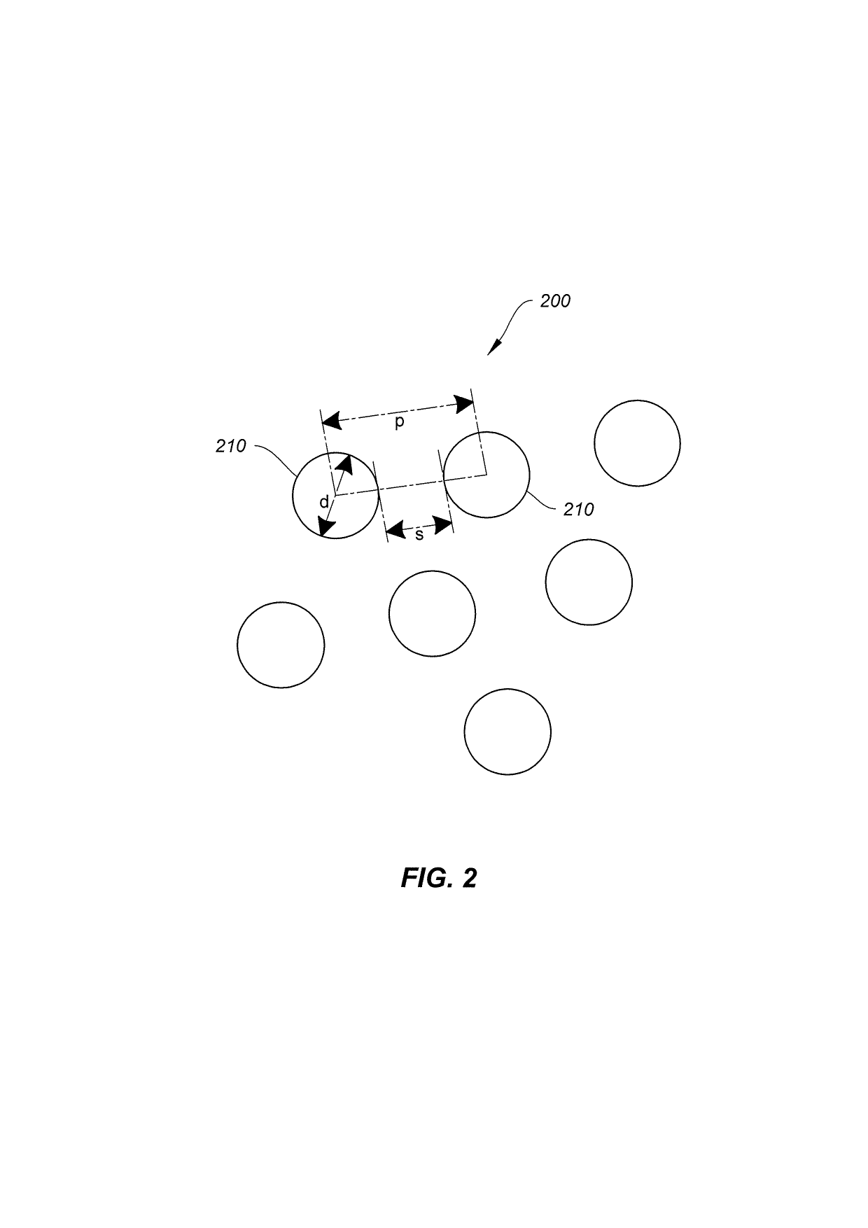

FIG. 2 is a simplified diagram showing a top view of the array of nanoholes 120 as shown in FIG. 1C and/or the array of nanoholes 132 as shown in FIG. 1D according to certain embodiments of the present invention. This diagram is merely an example, which should not unduly limit the scope of the claims. One of ordinary skill in the art would recognize many variations, alternatives, and modifications.

As shown in FIG. 2, there are multiple nanoholes 210 as parts of an array. For example, the nanoholes 210 are the nanoholes 120. In another example, the nanoholes 210 are the nanoholes 132. In one embodiment, the array of nanoholes 210 is characterized by hole size and sidewall thickness. For example, the hole size ranges from 5 nm-500 nm, and the sidewall thickness ranges from 5 nm-500 nm. In another example, the hole size ranges from 20 nm-40 nm, and the sidewall thickness ranges from 40 nm-60 nm. In yet another example, if the nanoholes 210 each have a circular cross-section in the top view, the hole size is represented by the diameter d of the nanohole 210, and the sidewall thickness is represented by the dimension s, which is equal to the hole-to-hole separation p (e.g., the pitch size) minus the diameter d of the nanohole 210, as shown in FIG. 2. In yet another example, the diameter d is about 30 nm on average, the pitch size is about 70 nm on average, and the sidewall separation s is about 40 nm on average.

As discussed above and further emphasized here, FIG. 2 is merely an example, which should not unduly limit the scope of the claims. One of ordinary skill in the art would recognize many variations, alternatives, and modifications. For example, the nanoholes 210 (e.g., the nanoholes 120, the nanoholes 132) are substantially uniformly distributed or not substantially uniformly distributed in the top view. In another example, the nanoholes 210 (e.g., the nanoholes 120, the nanoholes 132) can have any shape for the cross-section in the top view (e.g., a non-circular cross-section in the top view). In yet another example, the sidewall thickness is fixed along the depth. In yet another example, the sidewall thickness varies with the depth.

In one embodiment, within each of the nanoholes 210 (e.g., the nanoholes 120, the nanoholes 132), there is no nanowire. In another embodiment, within each of the nanoholes 210 (e.g., the nanoholes 120, the nanoholes 132), there are one or more nanowires, which, for example, are generated by the anisotropic wet etching process.

According to some embodiments, referring to FIG. 2 and FIG. 1D, the structure 130 with the array of nanoholes 132 can significantly enhance the thermal resistivity via strong boundary scattering of phonons transporting through the porous structure 130 while maintaining low electron scattering in order to maintain excellent electrical conductance, both low thermal conductivity and high electrical conductivity being desirable for certain high-performance thermoelectric devices.

According to some embodiments, referring to FIG. 2 and FIG. 1D, the sidewall thickness is important for thermoelectric conversion. For example, the sidewall thickness can be adjust in one or more of the following ways:

(1) In the process for applying the mask 110 onto the substrate surface 102 of the substrate 100, during the photolithography, overexposing the one or more photoresist materials to increase the hole size and therefore reduce the sidewall thickness;

(2) In the process for forming the multiple nanoholes 120 in the substrate 100, during the anisotropic wet etching process with an etchant solution, adjusting the etchant concentration to change the degree of anisotropicity in order to reduce the sidewall thickness at certain depths into the substrate 100; and/or

(3) After the nanoholes 120 and/or the nanoholes 132 are formed, oxidizing the nanoholes and then removing the resulting oxide in order to reduce the sidewall thickness.

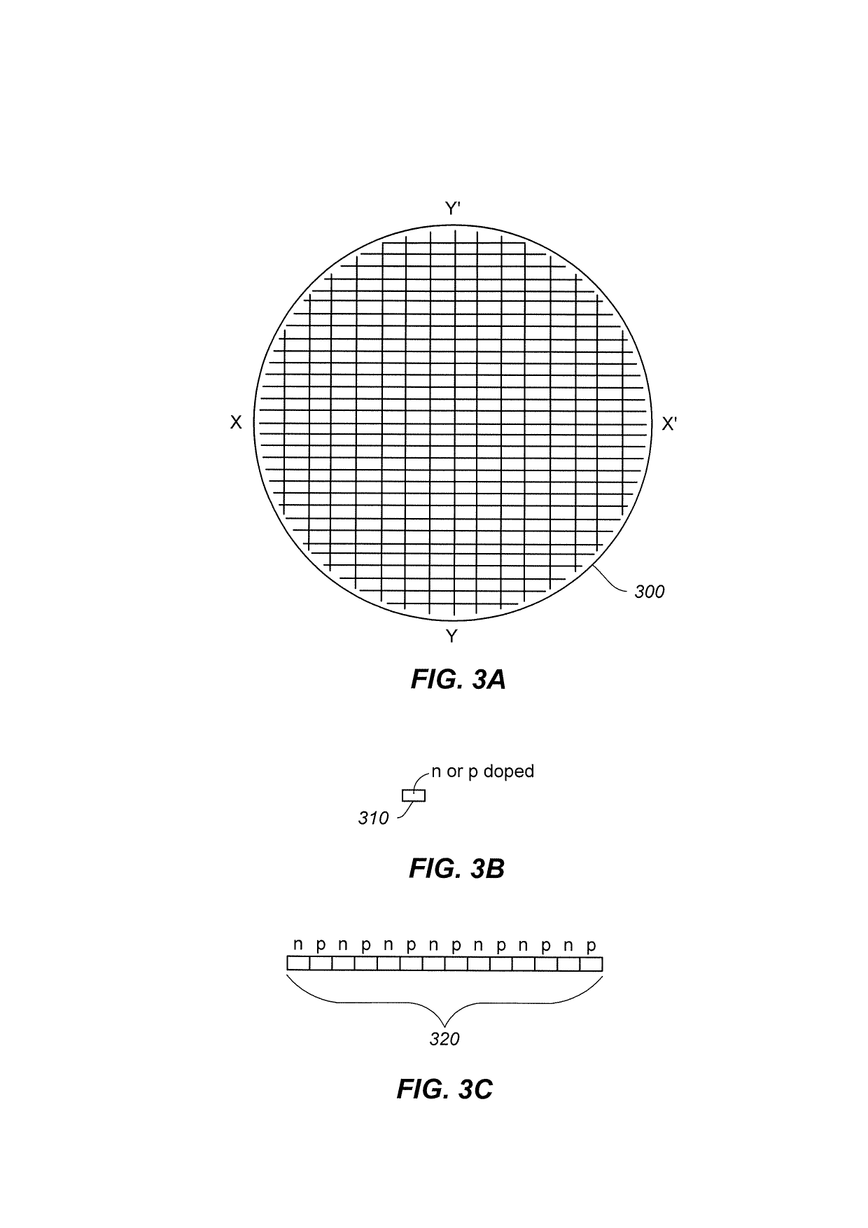

FIG. 3A is a simplified diagram showing a top view of a substrate for making one or more arrays of nanoholes in the substrate 100 according to an embodiment of the present invention. This diagram is merely an example, which should not unduly limit the scope of the claims. One of ordinary skill in the art would recognize many variations, alternatives, and modifications.

As shown in FIG. 3A, a substrate 300 is patterned for forming a plurality of patches in order to fabricate one or more arrays of nanoholes in each patch (e.g., each die). In one embodiment, each patch is used as the substrate 100, and within each patch, one or more arrays of nanoholes are fabricated as shown in FIGS. 1A-1D. In another embodiment, the substrate 300 is a silicon wafer being overlaid by a mask material based on a pre-determined pattern with a series of X-X′ lines and Y-Y′ lines. For example, the X-X′ lines are used to mark corresponding dies to be diced for forming multiple stripes. In another example, the Y-Y′ lines are used to cover wider surface area for marking a plurality of contact regions, where the substrate material are to be removed and refilled with one or more conductive materials to form thermal and electrical contacts. In yet another example, the Y-Y′ lines are also used to make different dies and optionally for guiding the wafer dicing.

As discussed above and further emphasized here, FIG. 3A is merely an example, which should not unduly limit the scope of the claims. One of ordinary skill in the art would recognize many variations, alternatives, and modifications. For example, the substrate 300 has a pattern that is different from what is defined by the series of X-X′ lines and Y-Y′ lines. In another example, each patch (e.g., each die) can have a size of any bulk dimension that varies from millimeters to centimeters or greater, and the shape of the die can be varied other than the rectangle as shown in the top view.

FIG. 3B is a simplified diagram showing a side view of a patch of the substrate 300 for making one or more arrays of nanoholes in the substrate 100 according to an embodiment of the present invention. This diagram is merely an example, which should not unduly limit the scope of the claims. One of ordinary skill in the art would recognize many variations, alternatives, and modifications.

In one embodiment, the substrate 300 (e.g., a silicon wafer) is diced along the X-X′ lines and the Y-Y′ lines to form multiple patches. For example, each patch 310 (e.g., each die) serves as the substrate 100. In another example, each patch 310 has a cross-section dimension in millimeter or centimeter range in the top view. In yet another example, a patch 310 is entirely doped to p type. In yet another example, a patch 310 is entirely doped to n-type.

In another embodiment, one or more metal materials are added in the regions defined by the Y-Y′ lines and form one or more metal contacts. For example, after the substrate 300 is diced, one or more portions of the one or more metal contacts stay in order to couple with the one or more arrays of nanoholes that are to be formed in each patch 310, resulting in one or more bulk nanohole structures each with two side thermal and electrical contacts.

FIG. 3C is a simplified diagram showing a side view of a stripe of the substrate 300 for making one or more arrays of nanoholes in the substrate 100 according to another embodiment of the present invention. This diagram is merely an example, which should not unduly limit the scope of the claims. One of ordinary skill in the art would recognize many variations, alternatives, and modifications.

In one embodiment, the substrate 300 (e.g., a silicon wafer) is diced along the X-X′ lines to form multiple stripes. For example, each stripe 320 includes multiple patches 310, which are doped alternately to n-type or p-type. In another example, different stripes 320 can have various number of pitches 310, and therefore also various length. In yet another example, each stripe 320 serves as one or more substrates 100.

In another embodiment, one or more metal materials are added in the regions defined by the Y-Y′ lines and form one or more metal contacts. For example, within each stripe 320, one or more bulk nanohole structures 130 is formed and bounded by the metal contacts (e.g., the metal contacts each serving as a thermal and electrical contact). In yet another embodiment, each strip 320 with multiple bulk nanohole structures 130 can be used to form one or more thermoelectric devices. For example, the thermal gradient is applied in the direction (e.g., in the X direction) that is the same as the direction of electrical current flow along the strip length. In another example, the thermal gradient is applied in the direction (e.g., in the Y direction) perpendicular to the direction of electrical current flow.

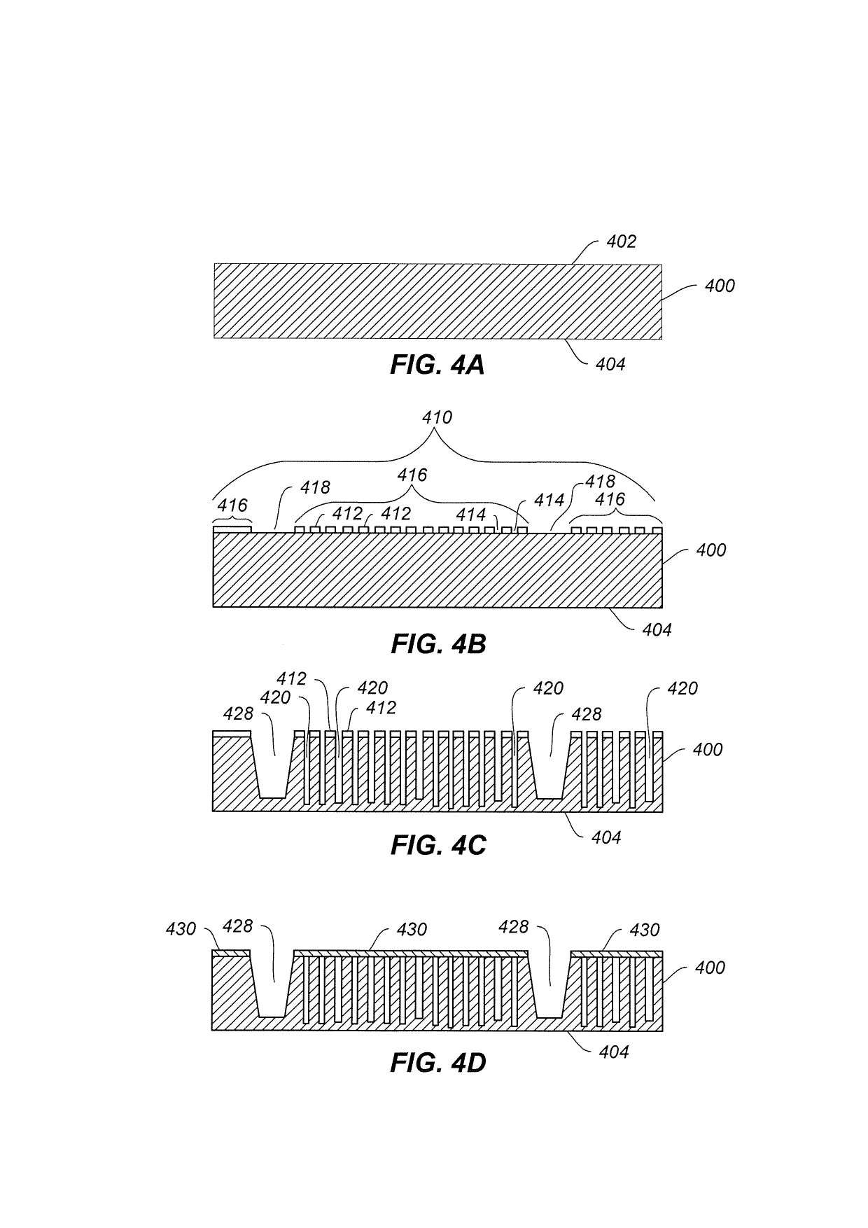

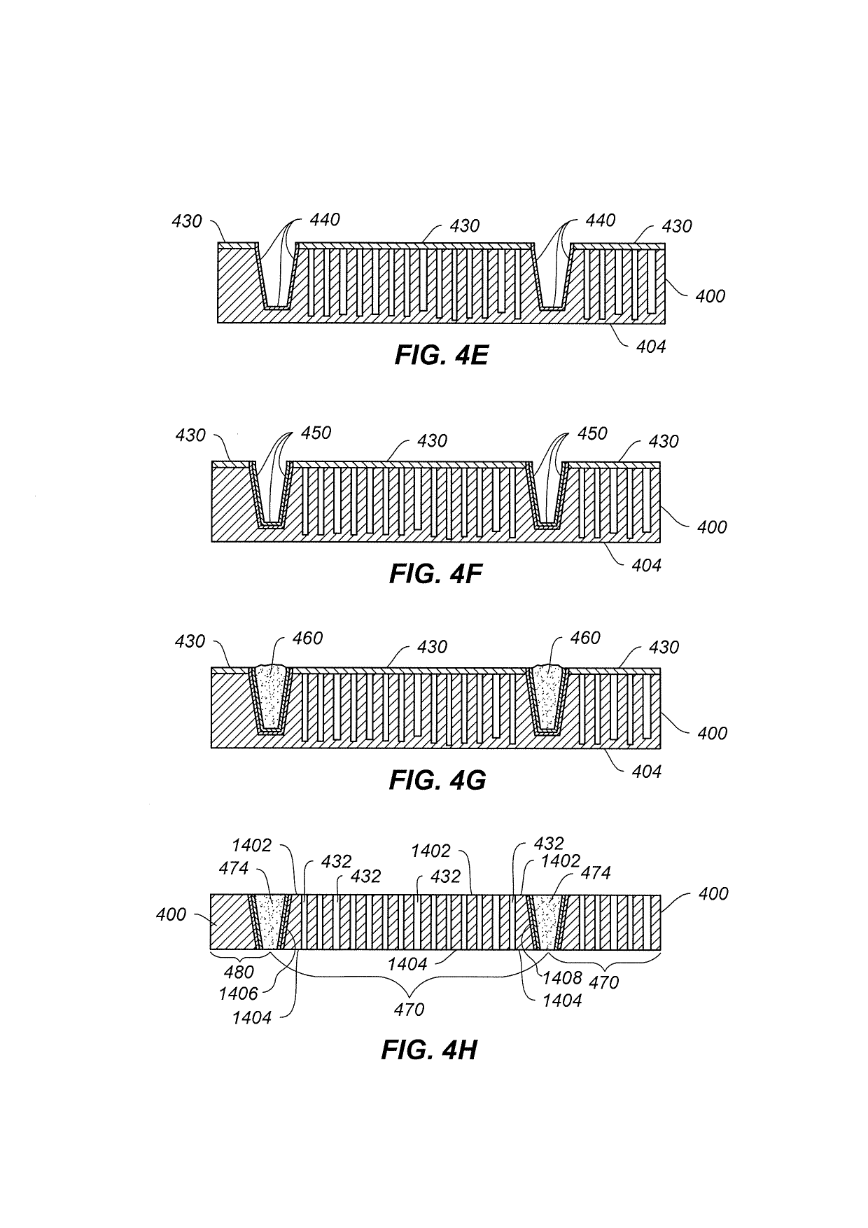

FIGS. 4A-4H are simplified diagrams showing a method for making one or more arrays of nanoholes in a substrate according to another embodiment of the present invention. These diagrams are merely examples, which should not unduly limit the scope of the claims. One of ordinary skill in the art would recognize many variations, alternatives, and modifications.

In one embodiment, the method for making one or more arrays of nanoholes in a substrate includes the following sequential processes (a) through (h):
(a) providing a substrate for forming one or more arrays of nanoholes (e.g., as shown in FIG. 4A);
(b) forming a mask on the substrate surface of the substrate (e.g., as shown in FIG. 4B);
(c) forming multiple nanoholes and multiple trenches in the substrate (e.g., as shown in FIG. 4C);
(d) removing the mask and forming another mask to cover the substrate except the trenches (e.g., as shown in FIG. 4D);
(e) forming a barrier layer to cover the trenches (e.g., as shown in FIG. 4E);
(f) forming a seed layer to cover the barrier layer in the trenches (e.g., as shown in FIG. 4F);
(g) forming one or more conductive materials to cover the seed layer and fill the trenches (e.g., as shown in FIG. 4G); and
(h) forming one or more structures with one or more arrays of nanoholes (e.g., as shown in FIG. 4H).
   The method described above is merely an example, which should not unduly limit the scope of the claims. One of ordinary skill in the art would recognize many variations, alternatives, and modifications. For example, one or more of the above listed processes are skipped. In another example, the above listed processes are performed in a different order. In yet another example, one or more additional processes are added.

As shown in FIG. 4A, a substrate 400 is provided for forming one or more arrays of nanoholes. For example, the substrate 400 includes substrate surfaces 402 and 404, and the substrate surface 404 is located opposite to the substrate surface 402. In another example, the substrate 400 is selected from various types of materials depending on embodiments. In one embodiment, a semiconductor substrate is selected as the substrate 400 for making one or more thermoelectric devices. For example, the substrate 400 is a silicon substrate (e.g., a single-crystal silicon substrate). In another example, the silicon substrate is a silicon wafer without special treatment (e.g., not a silicon-on-insulator wafer). In yet another example, the silicon substrate is uniformly doped into an n-type semiconductor or a p-type semiconductor. In yet another example, the silicon substrate is pattern-doped so that the n-type doping and the p-type doping are performed alternately in alternate patches respectively across the wafer.

As shown in FIG. 4B, a mask 410 is formed on the substrate surface 402 of the substrate 400. In one embodiment, the mask 410 includes multiple mask regions 416. For example, a mask region 416 extends to a bulk dimension of about several millimeters to centimeters or greater in the top view. In another example, different mask regions 416 are separated by corresponding boundary regions 418. In yet another example, a boundary region 418 has a size that is about several hundreds of microns in the top view. In yet another example, within each boundary region 418, the substrate surface 402 is exposed.

In another embodiment, at least one mask region 416 includes multiple mask islands 412 separated by multiple holes 414. For example, within each hole 414, the substrate surface 402 is exposed. In yet another example, the holes 414 are in nanoscopic scale, and the hole-to-hole separations (e.g., the pitch sizes) are also in nanoscopic scale. According to one embodiment, one or more co-polymer materials including metal particles are used to form the mask 410. According to another embodiment, one or more photoresist materials are used to pattern another inorganic material layer in order to form the mask 410.

As shown in FIG. 4C, multiple nanoholes 420 and multiple trenches 428 are formed in the substrate 400. In one embodiment, the nanoholes 420 are formed by applying an etching process (e.g., an anisotropic dry etching process, an anisotropic wet etching process with an etchant solution) through the holes 414, and the trenches 428 are formed by applying the etching process through the boundary regions 418.

In another embodiment, the nanoholes 420 are substantially vertical to the substrate surface 402, extending into the substrate 400 with corresponding depths. For example, the corresponding depths each exceed 100 μm. In another example, the corresponding depths each are at least 200 μm. In yet another example, the corresponding depths each are at least 400 μm. In yet another example, the corresponding depths each are at least 500 μm. In yet another example, the corresponding depths each are up to the total thickness of the substrate 400. In yet another embodiment, the trenches 428 have corresponding widths each of a few tens or hundreds of microns or greater, and corresponding depths approximately equal to the corresponding depths of the nanoholes 420.

In yet another embodiment, the nanoholes 420 that correspond to the same mask region 416 form an array of nanoholes 420, and two adjacent arrays of nanoholes 420 are separated by at least a trench 428. For example, the density of the array of nanoholes 420 has a hole density characterized by separations of the holes 414 (e.g., the pitch sizes). In another example, the average pitch size is about 70 nm. In yet another embodiment, the cross-sectional areas of corresponding nanoholes 420 determine the porosity of the resulting substrate structure as shown in FIG. 4C.

According to one embodiment, a top view of the array of nanoholes 420 as shown in FIG. 4C is depicted in the simplified diagram of FIG. 2, where the nanoholes 210 are the nanoholes 420. According to another embodiment, the mask 410 can be applied over any bulk-like thickness dimension so that one or more arrays of nanoholes 420 can be formed across the surface regions with the same bulk-like thickness dimension.

According to some embodiments, the anisotropic wet etching process can create roughened and/or porous sidewall surfaces for the nanoholes 420 and therefore reduce the thermal conductivity. According to certain embodiments, the nanoholes 420 are formed by applying an anisotropic etching process with an etchant solution that includes HF, AgNO₃, and H₂O. For example, the molar concentration of HF in the etchant solution varies from 2M to 10M. In another example, the molar concentration of AgNO₃ in the etchant solution varies from 0.001M to 0.5M. In yet another example, other molar concentrations vary depending on the etching parameters desired. In yet another embodiment, KNO₃ is added to the etchant solution. In one example, the KNO₃ is added to the etchant solution after a certain time period of initial etching without KNO₃ in the etchant solution. In another example, KNO₃ is added to the etchant solution all at once. In yet another example, KNO₃ is added to the etchant solution continuously at a predetermined rate. In yet another example, KNO₃ is added to the etchant solution to maintain the proper balance between Ag and Ag+ to control the etching rate, the anisotropy, and/or other etch characteristics. In yet another embodiment, other oxidizing agents other than KNO₃ are added to the etchant solution. In yet another embodiment, the anisotropic etching process of the substrate 400 includes multiple subprocesses. In one example, a first etchant solution including HF, AgNO₃, and H₂O is used for a first time period and then a second etchant solution including HF, H₂O₂, and H₂O is used for a second time period. In another example, a third etchant solution including HF, AgNO₃, and H₂O is used for a third time period and then a fourth etchant solution including HF, Fe(NO₃)₃, and H₂O is used for a fourth time period. According to some embodiments, the anisotropic dry etching process is a plasma dry etching process.

As shown in FIG. 4D, the mask 410 is removed, and then another mask 430 is formed to cover the substrate 400 except the trenches 428. For example, the mask 430 covers the nanoholes 420 but does not cover the trenches 428. In one embodiment, the removal of the mask 410 uses chemical treatment and/or mechanical polishing. In another embodiment, the formation of the mask 430 includes filling the nanoholes 420 and covering at least the parts of the substrate surface 420 that were covered by the mask 410 as shown in FIG. 4B.

As shown in FIG. 4E, a barrier layer 440 is formed to cover the trenches 428. For example, the barrier layer 440 covers the wall region and the bottom region of each trench 428. In another example, the barrier layer 440 can substantially prevent any metal material that is to be used to fill a trench 428 from diffusing into the substrate 400.

In one embodiment, the barrier layer 440 includes titanium nitride and/or tungsten nitride. In another embodiment, the barrier layer 440 includes tungsten silicide and/or tungsten nitride. In yet another embodiment, the barrier layer 440 includes titanium silicide and/or titanium nitride. In yet another embodiment, the barrier layer 440 use the same one or more materials used for the mask 430.

As shown in FIG. 4F, a seed layer 450 is formed to cover the barrier layer 440 in the trenches 428. For example, the seed layer 450 is conformal with the barrier layer 440. In another example, the seed layer 450 can facilitate the bounding between the barrier layer 440 and the metal material that is to be used to fill in the trenches 428. In yet another example, the seed layer 450 is a thin copper layer. In yet another example, the seed layer 450 is formed by a process used for forming conductive and/or metallic contacts in a semiconductor substrate.

As shown in FIG. 4G, one or more conductive materials 460 are formed to cover the seed layer 450 and fill the trenches 428. For example, the one or more conductive materials 460 include copper deposited by electroplating. In another example, the one or more conductive materials 460 include a metal silicide material deposited by sputtering and then annealed by rapid thermal anneal after the deposition.

As shown in FIG. 4H, one or more structures 470 with one or more arrays of nanoholes 472 are formed. In one embodiment, after the formation of the one or more conductive materials 460, both sides of the substrate 400 are polished, including polishing one side of the substrate 400 from the substrate surface 404. For example, the mask 430 and one or more portions of the one or more conductive materials 460 are removed by the polishing process. In another example, one structure 470 is in direct contact with another structure 480 that includes a part of the conductive material 474 and a part of the substrate 400 without any nanohole.

In another embodiment, each structure 470 includes an array of nanoholes 432 and at least parts of two conductive materials 474, and the substrate 400 includes two substrate surfaces 1402 and 1404. For example, the array of nanoholes 432 is sandwiched by the two conductive materials 474. In another yet example, the part of one of the two conductive materials 474 serves as a thermal and electrical contact region on one side of the array of nanoholes 432 (e.g., serving as a thermal and electrical contact to a substrate surface 1406 of the substrate 400) for the corresponding structure 470. In yet another example, the part of the other one of the two conductive materials 474 serves as a thermal and electrical contact region on another side of the array of nanoholes 432 (e.g., serving as a thermal and electrical contact to a substrate surface 1408 of the substrate 400) for the corresponding structure 470. In yet another example, the two conductive materials 474 are the remaining portions of the corresponding conductive materials 460 after the polishing process. According to one embodiment, the substrate surface 1406 extends from the substrate surface 1402 towards the substrate surface 1404. For example, the substrate surface 1406 is in direct contact with both the substrate surfaces 1402 and 1404. According to another embodiment, the substrate surface 1408 extends from the substrate surface 1402 towards the substrate surface 1404. For example, the substrate surface 1408 is in direct contact with both the substrate surfaces 1402 and 1404.

In yet another embodiment, the nanoholes 432 are parallel with each other (e.g., being vertically-aligned nanoholes). For example, the nanoholes 432 are either the same as the corresponding nanoholes 420 or shorter than the corresponding nanoholes 420, respectively. In another example, each of the nanoholes 432 has a depth that is larger than 100 μm. In yet another example, each of the nanoholes 432 has a depth that is larger than 200 μm. In yet another example, each of the nanoholes 432 has a depth that is larger than 400 μm. In yet another example, each of the nanoholes 432 has a depth that is larger than 500 μm.

In yet another embodiment, the cross-section of the structure 470 (e.g., the cross-section perpendicular to the vertical depth direction) can be in millimeters, centimeters, or as large as the whole substrate size. For example, the structure 470 is a bulk nanohole structure.

In another example, by adjusting the masking process as shown in FIG. 4B and/or the etching process as shown in FIG. 4C, the array of nanoholes 432 for the structure 470 can correspond to different densities and/or different porosities. In yet another embodiment, the structure 470 includes a stand-alone array of nanoholes 432. In yet another embodiment, a top view of an array of nanoholes 432 as shown in FIG. 4H is depicted in the simplified diagram of FIG. 2, where the nanoholes 210 are the nanoholes 432.

As discussed above and further emphasized here, FIGS. 4A-4H are merely examples, which should not unduly limit the scope of the claims. One of ordinary skill in the art would recognize many variations, alternatives, and modifications. For example, the structure that includes one or more structures 470 as shown in FIG. 4H is further processed to form one or more electronic devices. In another example, during the further processing, the structure is diced so that each structure 470 becomes a die of bulk nanohole structure. In yet another example, after the further processing, the one or more structures 470 form one or more thermoelectric (TE) legs as one or more parts of a thermoelectric device.

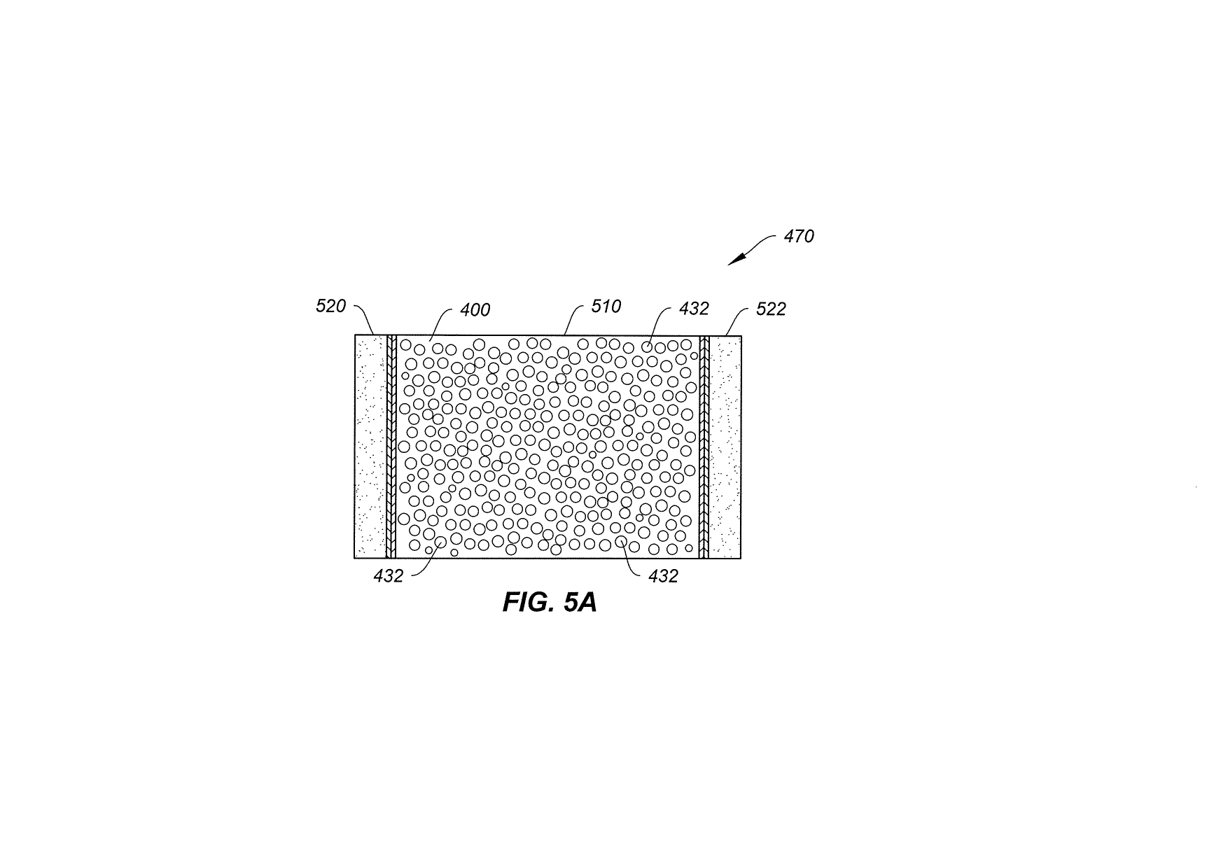

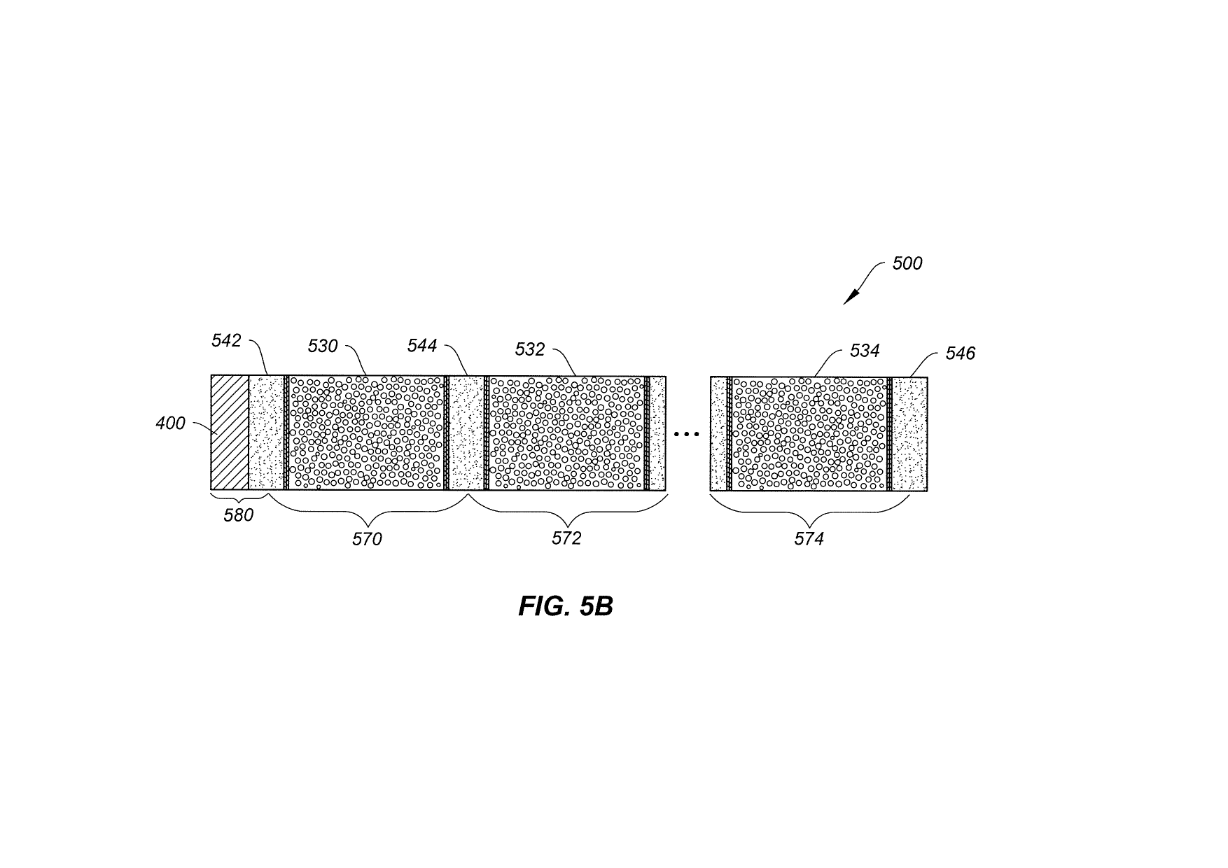

FIG. 5A is a simplified diagram showing a top view of the structure 470 as shown in FIG. 4H according to one embodiment of the present invention. This diagram is merely an example, which should not unduly limit the scope of the claims. One of ordinary skill in the art would recognize many variations, alternatives, and modifications.

As shown in FIG. 5A, the structure 470 has a rectangular shape in the top view, including an array region 510 and two conductive regions 520 and 522. In one embodiment, the array region 510 includes an array of nanoholes 432. For example, the array of nanoholes 432 have been fabricated from parts of the substrate 400 that correspond to a mask region 416. In another example, the nanoholes 432 distribute substantially uniformly through the array region 510. In another embodiment, the two conductive regions 520 and 522 are the parts of two conductive materials 474 that belong to the same structure 470 as shown in FIG. 4H. For example, the conductive region 520 forms a thermal and electrical contact with the array region 510, and the conductive region 522 forms another thermal and electrical contact with the array region 510. In yet another embodiment, the structure 470 is made from the patch 310 as shown in FIG. 3B (e.g., the patch 310 as at least a part of the substrate 400).

According to one embodiment, the structure 470 is a single die. For example, the structure 470 has dimensions in both directions within the top view, ranging from millimeters and above. According to another embodiment, the structure 470 can form a thermoelectric (TE) leg. For example, if the substrate material in the structure 470 is doped to n type, the structure 470 serves as an n-type thermoelectric leg. In another example, if the substrate material in the structure 470 is doped to p type, the structure 470 serves as a p-type thermoelectric leg.

As shown in FIG. 4H and/or FIG. 5A, the array of nanoholes 432 embedded within certain remaining parts of the substrate 400 (e.g., a single-crystal silicon substrate) provides a bulk-sized block of one or more materials according to certain embodiments. In one embodiment, the bulk-sized block has strong mechanical strength (e.g., in comparison with some other porous or amorphous materials). In another embodiment, the bulk-sized block has substantially high thermal resistance across a temperature gradient and also has low electrical resistance in order to effectively carry an electrical current that is induced by thermoelectric effect through the bulk-sized body. For example, the temperature gradient is applied between the conductive regions 520 and 522, and the electrical current flows between the conductive regions 520 and 522.

FIG. 5B is a simplified diagram showing a top view of a structure that includes multiple structures 470 as shown in FIG. 4H according to another embodiment of the present invention. This diagram is merely an example, which should not unduly limit the scope of the claims. One of ordinary skill in the art would recognize many variations, alternatives, and modifications.

As shown in FIG. 5B, the structure 500 includes multiple structures 570, 572, and 574. For example, each of these multiple structures 570, 572, and 574 is the same as the structure 470. In another example, the structure 570 is in direct contact with the structure 572. In yet another example, the structure 572 is either in direct contact with the structure 574, or in direct contact with one or more similar structures (e.g., one or more structures 470), which are in turn in direct contact with the structure 574.

In one embodiment, the structure 500 includes array regions 530, 532, and 534. For example, each of these array regions 530, 532, and 534 is the same as the array region 510. In another embodiment, the structure 500 includes conductive regions 542, 544, and 546. For example, each of the conductive regions 542, 544, and 546 is the same as the region 474. In another example, the conductive region 544 is a combination of the conductive region 520 of the structure 570 and the conductive region 522 of the structure 572. In yet another embodiment, the structure 500 includes a structure 580, which is the same as the structure 480 as shown in FIG. 4H. In yet another embodiment, the structure 500 is made from the stripe 320 as shown in FIG. 3C (e.g., the stripe 320 as at least a part of the substrate 400).

According to one embodiment, the substrate material of the structure 500 is doped to n type. For example, the structure 500 serves as an n-type thermoelectric leg. In another example, the temperature gradient is applied between the conductive regions 542 and 546, and the electrical current flows between the conductive regions 542 and 546. According to another embodiment, the substrate material of the structure 500 is doped to p type. For example, the structure 500 serves as a p-type thermoelectric leg. In another example, the temperature gradient is applied between the conductive regions 542 and 546, and the electrical current flows between the conductive regions 542 and 546.

According to yet another embodiment, the substrate material corresponding to two array regions that are separated by a conductive region (e.g., by the conductive region 542 or by the conductive region 544) are doped alternately to n type or p type. For example, if the substrate material for the array region 530 is doped to n type, the substrate material for the array region 532 is doped to p type. In another example, if the substrate material for the array region 530 is doped to p type, the substrate material for the array region 532 is doped to n type. In yet another example, by alternating the doping types, the structure 500 can be directly applied as thermoelectric devices in one or more configurations with each structure 510 (e.g., the structure 570, 572, or 574) being coupled thermally and electrically in different manners and/or orientations.

As discussed above and further emphasized here, FIGS. 5A-5B are merely examples, which should not unduly limit the scope of the claims. One of ordinary skill in the art would recognize many variations, alternatives, and modifications. For example, the nanoholes 432 are substantially uniformly distributed or not substantially uniformly distributed in the top view. In another example, the nanoholes 432 can have any shape for the cross-section in the top view (e.g., a non-circular cross-section in the top view).

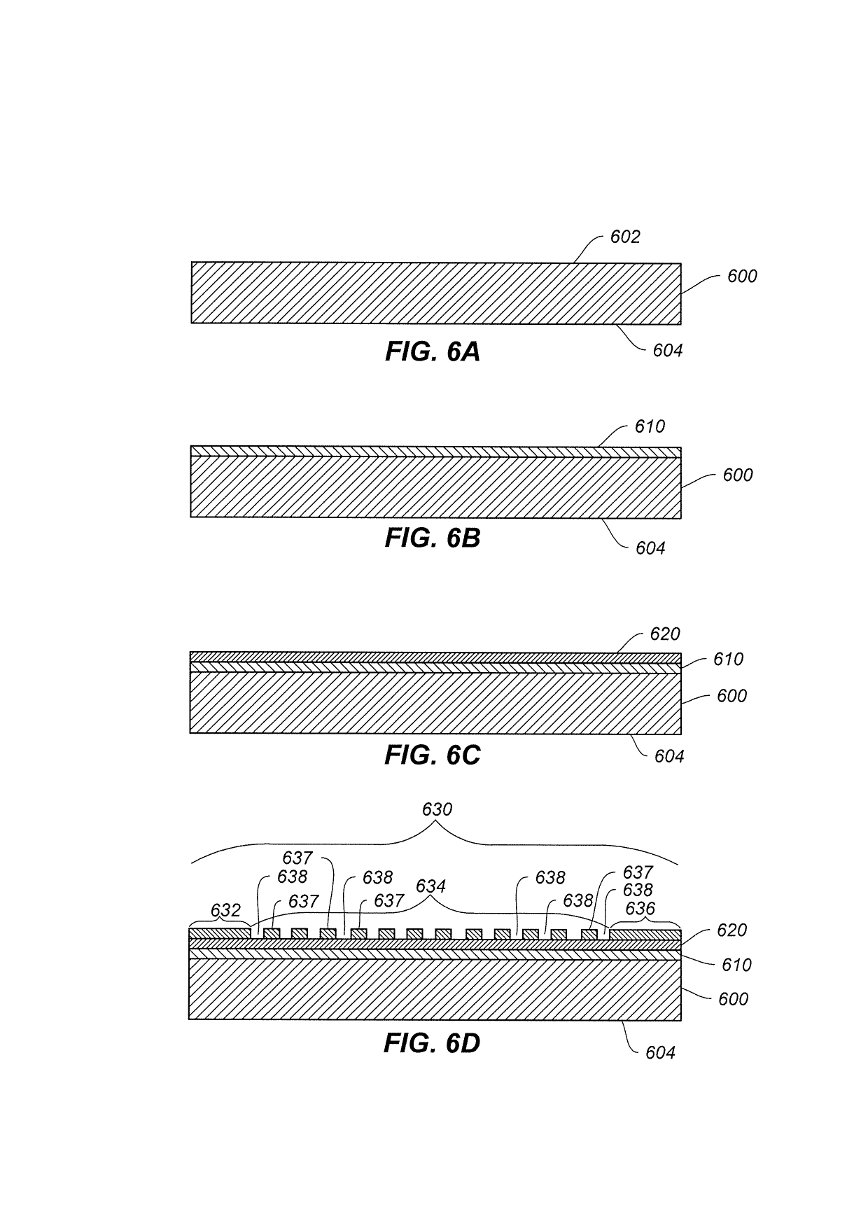

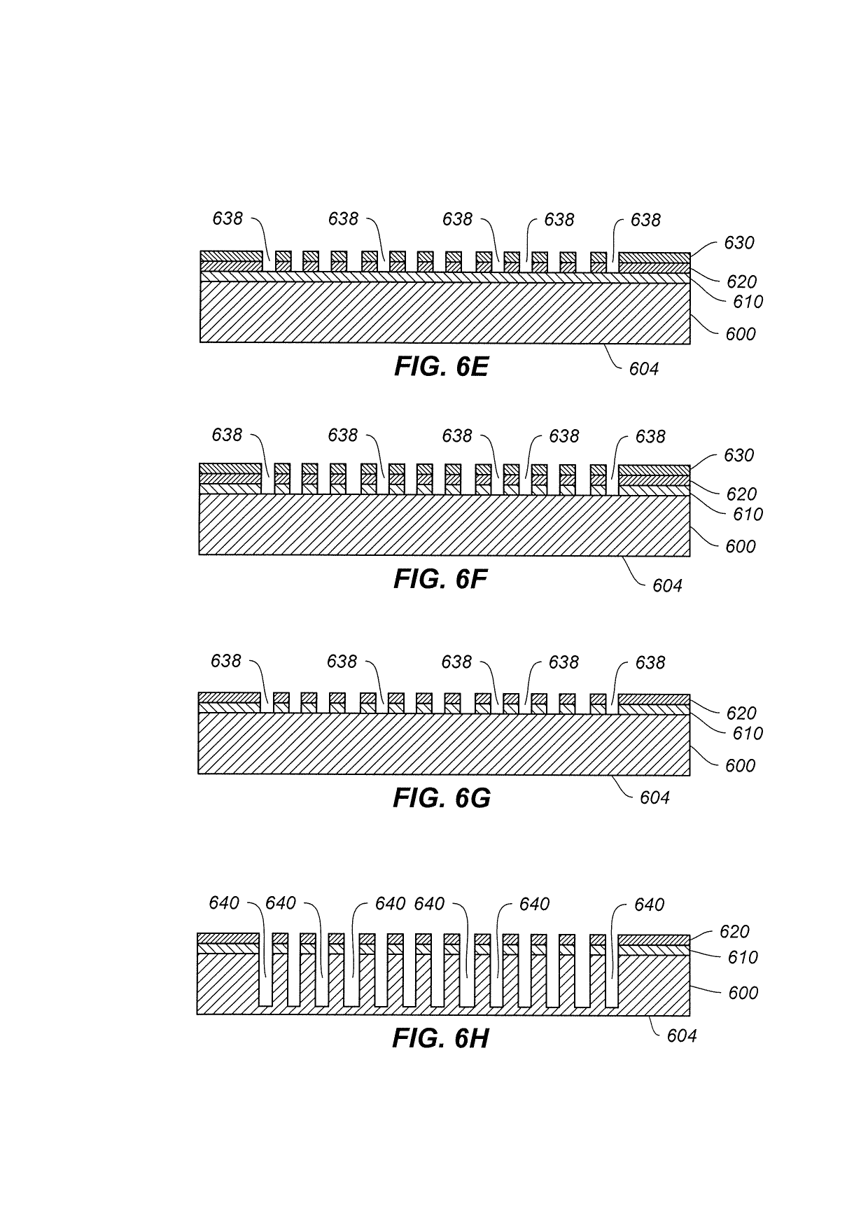

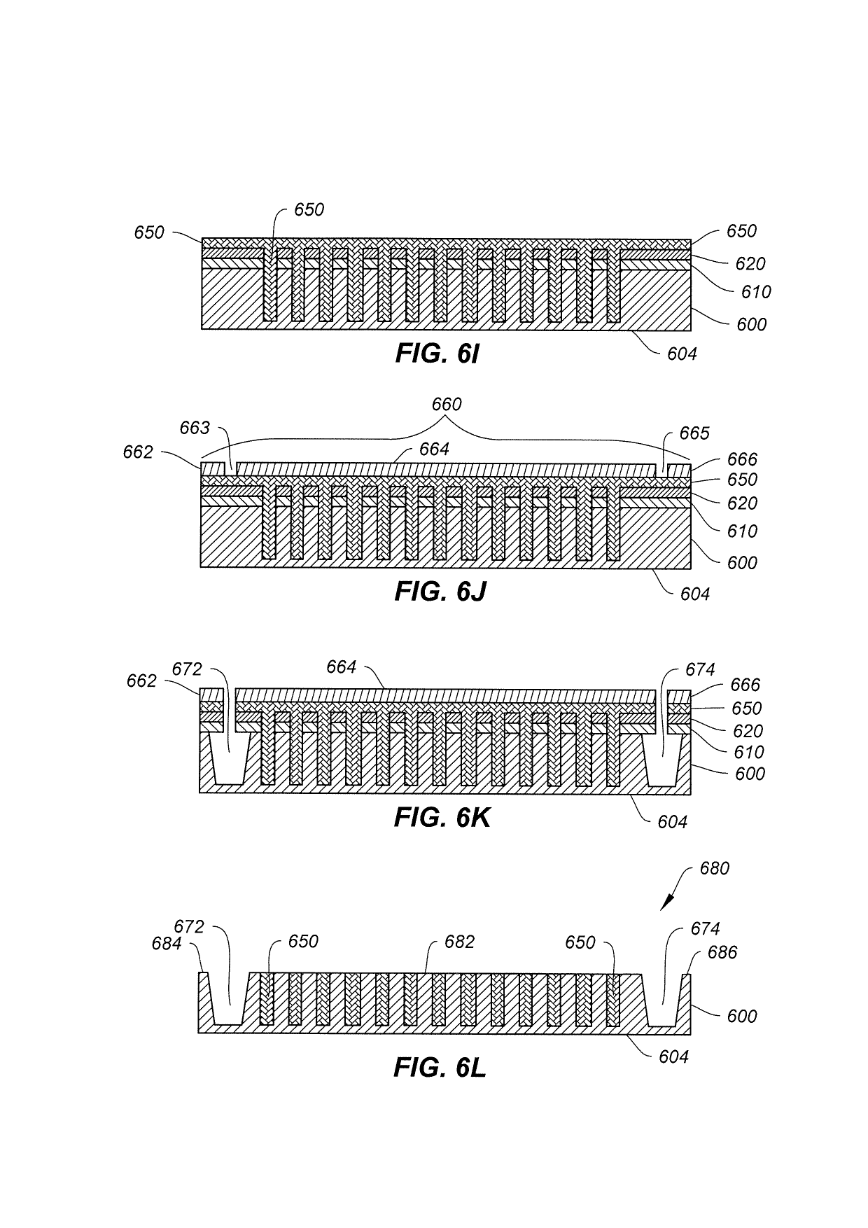

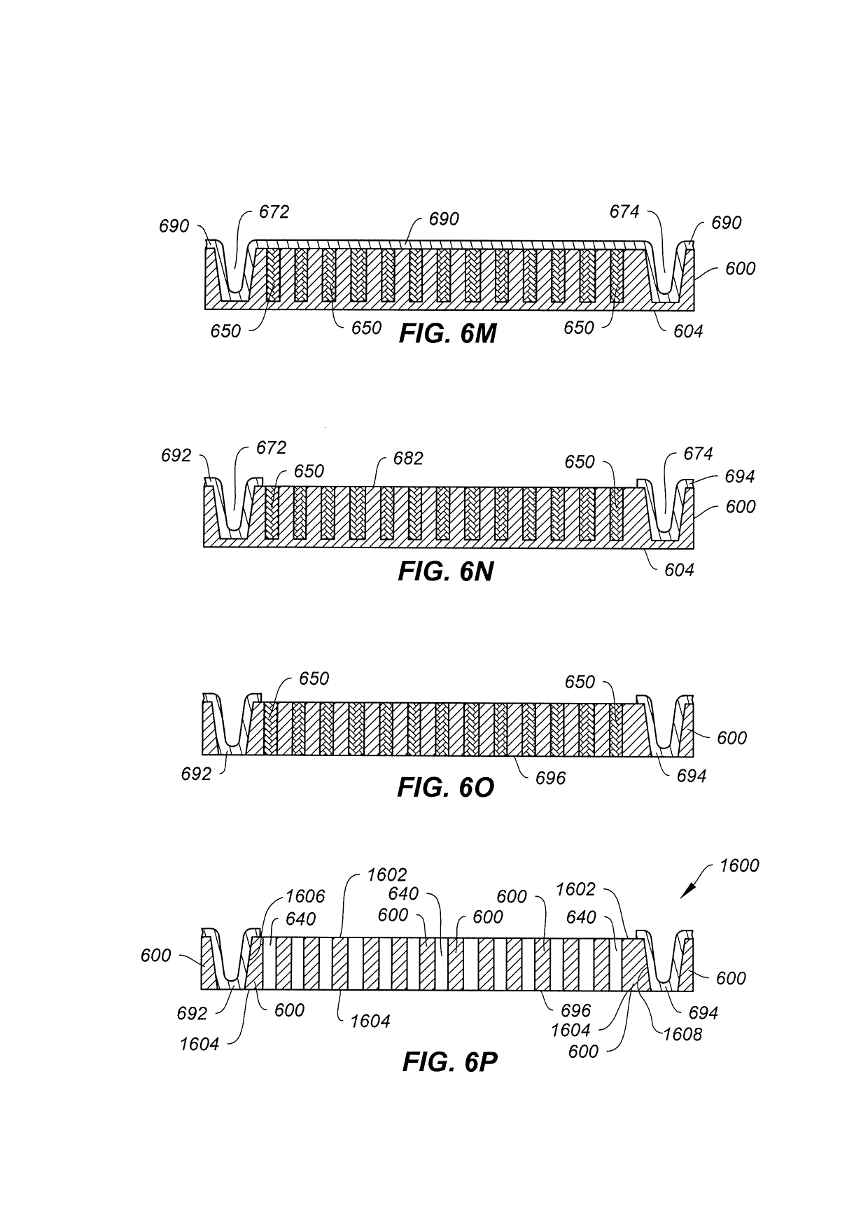

FIGS. 6A-6P are simplified diagrams showing a method for making one or more arrays of nanoholes in a substrate according to yet another embodiment of the present invention. These diagrams are merely examples, which should not unduly limit the scope of the claims. One of ordinary skill in the art would recognize many variations, alternatives, and modifications.

In one embodiment, the method for making one or more arrays of nanoholes in a substrate includes the following sequential processes (a) through (p):
(a) providing a substrate for forming one or more arrays of nanoholes (e.g., as shown in FIG. 6A);
(b) forming an oxide layer on the substrate surface of the substrate (e.g., as shown in FIG. 6B);
(c) forming a silicon carbide layer on the oxide layer (e.g., as shown in FIG. 6C);
(d) forming a mask on the silicon carbide layer (e.g., as shown in FIG. 6D);
(e) etching the silicon carbide layer within the holes (e.g., as shown in FIG. 6E);
(f) etching the oxide layer within the holes (e.g., as shown in FIG. 6F);
(g) removing the mask so that the silicon carbide layer is exposed between the holes (e.g., as shown in FIG. 6G);
(h) forming multiple nanoholes in the substrate (e.g., as shown in FIG. 6H);
(i) filling the nanoholes with one or more oxide materials (e.g., as shown in FIG. 6I);
(j) forming a mask on the one or more oxide materials (e.g., as shown in FIG. 6J);
(k) forming trenches in the substrate (e.g., as shown in FIG. 6K);
(l) removing the mask, the one or more oxide materials that are not in the nanoholes, the silicon carbide layer, and the oxide layer to form a structure (e.g., as shown in FIG. 6L);
(m) forming one or more conductive materials overlying the previously formed structure (e.g., as shown in FIG. 6M);
(n) removing portions of the one or more conductive materials so that the one or more oxide materials filling the nanoholes are not covered by the one or more conductive materials, but the one or more conductive materials still at least partially fill the trenches and cover the substrate surfaces (e.g., as shown in FIG. 6N);
(o) polishing one side of the substrate from the substrate surface (e.g., as shown in FIG. 6O); and
(p) removing the one or more oxide materials that are in the nanoholes to form a structure (e.g., as shown in FIG. 6P).
   The method described above is merely an example, which should not unduly limit the scope of the claims. One of ordinary skill in the art would recognize many variations, alternatives, and modifications. For example, one or more of the above listed processes are skipped. In another example, the above listed processes are performed in a different order. In yet another example, one or more additional processes are added.

As shown in FIG. 6A, a substrate 600 is provided for forming one or more arrays of nanoholes. For example, the substrate 600 includes substrate surfaces 602 and 604, and the substrate surface 604 is located opposite to the substrate surface 602. In another example, the substrate 600 is selected from various types of materials depending on embodiments. In one embodiment, a semiconductor substrate is selected as the substrate 600 for making one or more thermoelectric devices. For example, the substrate 600 is a silicon substrate (e.g., a single-crystal silicon substrate). In another example, the silicon substrate is a silicon wafer without special treatment (e.g., not a silicon-on-insulator wafer). In yet another example, the silicon substrate is uniformly doped into an n-type semiconductor or a p-type semiconductor. In yet another example, the silicon substrate is pattern-doped so that the n-type doping and the p-type doping are performed alternately in alternate patches respectively across the wafer.

As shown in FIG. 6B, an oxide layer 610 is formed on the substrate surface 602 of the substrate 600. For example, the oxide layer 610 includes silicon dioxide that is formed by preparing the silicon substrate 600 and then thermally oxidizing the top portion of the prepared silicon substrate 600. In another example, the oxide layer 610 is formed by a low-temperature oxidation process.

As shown in FIG. 6C, a silicon carbide layer 620 is formed on the oxide layer 610. For example, the silicon carbide layer 620 is deposited by a chemical vapor deposition process and/or a sputtering process.

As shown in FIG. 6D, a mask 630 is formed on the silicon carbide layer 620. In one embodiment, the mask 630 includes mask regions 632, 634, and 636. For example, in the mask regions 632 and 636, the substrate surface 602 is completely covered by the mask. In another example, the mask region 634 extends to a bulk dimension of about several millimeters to centimeters or greater in the top view.

According to one embodiment, the mask region 634 includes multiple mask islands 637 separated by multiple holes 638. For example, within each hole 638, the silicon carbide layer 620 is exposed. In another example, a hole 638 separates a mask island 637 from either another mask island 637 or the mask region 632 or 636. In yet another example, the holes 638 are in nanoscopic scale, and the hole-to-hole separations (e.g., the pitch sizes) are also in nanoscopic scale. According to another embodiment, one or more co-polymer materials including metal particles are used to form the mask 630. According to yet another embodiment, one or more photoresist materials are used to pattern another inorganic material layer in order to form the mask 630.

As shown in FIG. 6E, the silicon carbide layer 620 is etched within the holes 638. For example, after the etch, within each hole 638, the oxide layer 610 is exposed. In another example, the etch is performed by a reactive ion etching process and/or a photoelectrochemical etching process. As shown in FIG. 6F, the oxide layer 610 is etched within the holes 638. For example, after the etch, within each hole 638, the substrate surface 602 is exposed. As shown in FIG. 6G, the mask 630 is removed so that the silicon carbide layer 620 is exposed between the holes 638.

As shown in FIG. 6H, multiple nanoholes 640 are formed in the substrate 600. In one embodiment, the nanoholes 640 are formed by applying an etching process (e.g., an anisotropic dry etching process, an anisotropic wet etching process with an etchant solution) through the holes 638. In another embodiment, the nanoholes 640 are substantially vertical to the substrate surface 602, extending into the substrate 400 with corresponding depths. For example, the corresponding depths each exceed 100 μm. In another example, the corresponding depths each are at least 200 μm. In yet another example, the corresponding depths each are at least 400 μm. In yet another example, the corresponding depths each are at least 500 μm. In yet another example, the corresponding depths each are up to the total thickness of the substrate 600.

In yet another embodiment, the nanoholes 640 form an array of nanoholes 640. For example, the density of the array of nanoholes 640 has a hole density characterized by separations of the holes 640 (e.g., the pitch sizes). In another example, the average pitch size is about 70 nm. In yet another embodiment, the cross-sectional areas of corresponding nanoholes 640 determine the porosity of the resulting substrate structure as shown in FIG. 6H.

According to one embodiment, a top view of the array of nanoholes 640 as shown in FIG. 6H is depicted in the simplified diagram of FIG. 2, where the nanoholes 210 are the nanoholes 640. According to another embodiment, the mask 610 can be applied over any bulk-like thickness dimension so that one or more arrays of nanoholes 640 can be formed across the surface regions with the same bulk-like thickness dimension.

According to some embodiments, the nanoholes 640 are formed in the substrate 600 by anisotropic wet chemical etching process for an extended period of time. For example, the structure as shown in FIG. 6G is first processed by an etchant solution containing AgNO₃/H₂O₂ with 1% HF in a short time period (e.g., a time period shorter than 30 seconds). As a result, a few silver particles deposit and stay over the exposed substrate surface 602 (e.g., the exposed silicon substrate surface 602). Further, the structure is subject to chemical etching of the substrate 600 (e.g., the silicon substrate 600) using H₂O₂/HF/H₂O/HNO₃ solution while the previously deposited silver particles serve as surfactant to drive the etching reaction with silicon specifically at the bottom of each hole 638. The etching process is extended further to cause the formation of the nanoholes 640. According to certain embodiment, the anisotropic dry etching process is a plasma dry etching process.

According to some embodiments, the anisotropic wet etching process can create roughened and/or porous sidewall surfaces for the nanoholes 640 and therefore reduce the thermal conductivity. According to certain embodiments, the nanoholes 640 are formed by applying an anisotropic etching process with an etchant solution that includes HF, AgNO₃, and H₂O. For example, the molar concentration of HF in the etchant solution varies from 2M to 10M. In another example, the molar concentration of AgNO₃ in the etchant solution varies from 0.001M to 0.5M. In yet another example, other molar concentrations vary depending on the etching parameters desired. In yet another embodiment, KNO₃ is added to the etchant solution. In one example, the KNO₃ is added to the etchant solution after a certain time period of initial etching without KNO₃ in the etchant solution. In another example, KNO₃ is added to the etchant solution all at once. In yet another example, KNO₃ is added to the etchant solution continuously at a predetermined rate. In yet another example, KNO₃ is added to the etchant solution to maintain the proper balance between Ag and Ag+ to control the etching rate, the anisotropy, and/or other etch characteristics. In yet another embodiment, other oxidizing agents other than KNO₃ are added to the etchant solution. In yet another embodiment, the anisotropic etching process of the substrate 600 includes multiple subprocesses. In one example, a first etchant solution including HF, AgNO₃, and H₂O is used for a first time period and then a second etchant solution including HF, H₂O₂, and H₂O is used for a second time period. In another example, a third etchant solution including HF, AgNO₃, and H₂O is used for a third time period and then a fourth etchant solution including HF, Fe(NO₃)₃, and H₂O is used for a fourth time period.

As shown in FIG. 6I, the nanoholes 640 are filled with one or more oxide materials 650. For example, the one or more oxide materials 650 are deposited into the nanoholes 640 using a plasma enhanced chemical vapor deposition process.

As shown in FIG. 6J, a mask 660 is formed on the one or more oxide materials 650. In one embodiment, the mask 660 includes mask regions 662, 664, and 666. For example, the mask regions 662 and 664 are separated by a boundary region 663, and the mask regions 664 and 666 are separated by a boundary region 665. In another example, in the mask regions 662, 664, and 666, the one or more oxide materials 650 are completely covered by the mask. In yet another example, the mask region 664 are located over the nanoholes 640.

In another embodiment, one or more photoresist materials (e.g., a photoresist material used for silicon processing) are used to pattern another inorganic material layer in order to form the mask 666.

As shown in FIG. 6K, trenches 672 and 674 are formed in the substrate 600. In one embodiment, through the boundary region 663, a portion of the one or more oxide materials 650, a portion of the silicon carbide layer 620, and a portion of the oxide layer 610 are removed, and through the boundary region 665, another portion of the one or more oxide materials 650, another portion of the silicon carbide layer 620, and another portion of the oxide layer 610 are removed. Afterwards, a portion of the substrate 600 is removed to form the trench 672, and another portion of the substrate 600 is removed to form the trench 674 according to certain embodiments.

In another embodiment, the removal of the portions of the substrate 600 (e.g., the etching of the portions of the silicon substrate 600) is less anisotropic than the removal of the corresponding portions of the one or more oxide materials 650, the corresponding portions of the silicon carbide layer 620, and the corresponding portions of the oxide layer 610. For example, the trenches 672 and 674 have widths that are larger than the widths of the removed corresponding portions of the one or more oxide materials 650, the removed corresponding portions of the silicon carbide layer 620, and the removed corresponding portions of the oxide layer 610, and the trenches 672 and 674 have depths that are approximately equal to the corresponding depths of the nanoholes 640. In another example, the widths of the trenches 672 and 674 are greater than a few hundreds of micrometers, a few millimeters or greater. In yet another example, the etching of the portions of the silicon substrate 600 is performed using the TMAH etching technique, although other wet or dry etching techniques can also be used.

As shown in FIG. 6L, the mask 660, the one or more oxide materials 650 that are not in the nanoholes 640, the silicon carbide layer 620, and the oxide layer 610 are removed to form a structure 680. For example, the structure 680 includes the nanoholes 640 filled with the one or more oxide materials 650 and sandwiched by the trenches 672 and 674. In another example, the one or more oxide materials 650 in the nanoholes 640 and the substrate material adjacent to the nanoholes 640 form a surface 682 between the trenches 672 and 674. In yet another example, the trench 672 is located between the surface 682 on one side and a substrate surface 684 on the opposite side, and the trench 674 is located between the surface 682 on one side and a substrate surface 686 on the opposite side.

In one embodiment, the mask 660 is removed by a chemical process. In another embodiment, the silicon carbide layer 620 and the oxide layer 610 are removed by a mechanical polishing process. In yet another embodiment, the trench 672 is used for forming a thermal and electrical contact of a nanohole structure associated with the array of nanoholes 640, and the trench 674 is also used for forming a thermal and electrical contact of the nanohole structure associated with the array of nanoholes 640.

As shown in FIG. 6M, one or more conductive materials 690 are formed overlying the previously formed structure 680. For example, the one or more conductive materials 690 cover the surface 682, at least partially fill the trenches 672 and 674, and cover the substrate surfaces 684 and 686. In another example, the one or more conductive materials 690 are formed through deposition, plating, and/or one or more other processes. In yet another example, a barrier layer and/or a seed layer are formed to cover at least the substrate surface within the trenches 672 and 674 before the one or more conductive materials 690 are deposited. In yet another example, the one or more conductive materials 690 include one or more metal materials with high conductivity.

As shown in FIG. 6N, portions of the one or more conductive materials 690 are removed so that the one or more oxide materials 650 filling the nanoholes 640 are not covered by the one or more conductive materials 690, but the one or more conductive materials 690 still at least partially fill the trenches 672 and 674 and cover the substrate surfaces 684 and 686. For example, the remaining portions of the one or more conductive materials 690 include one or more conductive materials 692 and one or more conductive materials 694.

In one embodiment, the one or more conductive materials 692 at least partially fill the trench 672, and also cover at least part of the surface 682 and the substrate surface 684. For example, the trench 672 has a depth that is approximately equal to the corresponding depths of the nanoholes 640, and the one or more conductive materials 692 within the trench 672 form a thermal and electrical contact with a side of the substrate material that is adjacent to one or more of the nanoholes 640. In another example, the one or more conductive materials 692 on the surface 682 and the substrate surface 684 can be used to extend the thermal and/or electrical path above the top end of the array of nanoholes 640 in order to form a thermal and/or electrical contact with one or more external terminals (e.g., one or more external electrodes).

In another embodiment, the one or more conductive materials 694 at least partially fill the trench 674, and also cover at least part of the surface 682 and the substrate surface 686. For example, the trench 674 has a depth that is approximately equal to the corresponding depths of the nanoholes 640, and the one or more conductive materials 694 within the trench 674 form a thermal and electrical contact with a side of the substrate material that is adjacent to one or more of the nanoholes 640. In another example, the one or more conductive materials 694 on the surface 682 and the substrate surface 686 can be used to extend the thermal and/or electrical path above the top end of the array of nanoholes 640 in order to form a thermal and/or electrical contact with one or more external terminals (e.g., one or more external electrodes).

As shown in FIG. 6O, one side of the substrate 600 is polished from the substrate surface 604. For example, the polishing process includes polishing the one or more conductive materials 692 and 694. In another example, the polishing process is performed using a chemical mechanical polishing process to provide a substantially leveled backend for all the nanoholes 640 and the one or more conductive materials 692 and 694. In yet another example, the backend for all the nanoholes 640 and the one or more conductive materials 692 and 694 forms a surface 696.

As shown in FIG. 6P, the one or more oxide materials 650 that are in the nanoholes 640 are removed to form a structure 1600. In one embodiment, the removal of the one or more oxide materials 650 uses optionally also one or more cleaning processes. In another embodiment, the structure 1600 includes an array of nanoholes 640 and the one or more conductive materials 692 and 694, and the substrate 600 includes two substrate surfaces 1602 and 1604. For example, the one or more conductive materials 692 and 694 are thermally and/or electrically coupled to the substrate material on the sides approximately in parallel to the depth direction of the nanoholes 640. In another example, the one or more conductive material 692 serves as a thermal and electrical contact to the substrate material on one side approximately in parallel to the depth direction of the nanoholes 640 (e.g., serving as a thermal and electrical contact to a substrate surface 1606 of the substrate 600), and the one or more conductive material 694 serves as a thermal and electrical contact to the substrate material on another side approximately in parallel to the depth direction of the nanoholes 640 (e.g., serving as a thermal and electrical contact to a substrate surface 1608 of the substrate 600). In yet another example, a top view of the array of nanoholes 640 as shown in FIG. 6P is depicted in the simplified diagram of FIG. 2, where the nanoholes 210 are the nanoholes 640. According to one embodiment, the substrate surface 1606 extends from the substrate surface 1602 towards the substrate surface 1604. For example, the substrate surface 1606 is in direct contact with both the substrate surfaces 1602 and 1604. According to another embodiment, the substrate surface 1608 extends from the substrate surface 1602 towards the substrate surface 1604. For example, the substrate surface 1608 is in direct contact with both the substrate surfaces 1602 and 1604.

In yet another embodiment, the nanoholes 640 are parallel with each other (e.g., being vertically-aligned nanoholes). For example, the nanoholes 640 as shown in FIG. 6P are either the same as the corresponding nanoholes 640 as shown in FIG. 6H or shorter than the corresponding nanoholes 640 as shown in FIG. 6H, respectively. In another example, each of the nanoholes 640 has a depth that is larger than 100 μm. In yet another example, each of the nanoholes 640 has a depth that is larger than 200 μm. In yet another example, each of the nanoholes 640 has a depth that is larger than 400 μm. In yet another example, each of the nanoholes 640 has a depth that is larger than 500 μm. In yet another embodiment, the structure 1600 is a bulk nanohole structure

As discussed above and further emphasized here, FIGS. 6A-6P are merely examples, which should not unduly limit the scope of the claims. One of ordinary skill in the art would recognize many variations, alternatives, and modifications. For example, the trenches 672 and 674 are completed filled with the one or more conductive materials 690. In another example, the trench 672 is completely filled with the one or more conductive materials 692, and the trench 674 is completely filled with the one or more conductive materials 694.

In one embodiment, the structure 1600 as shown in FIG. 6P is further processed to form one or more parts of a thermoelectric device. For example, during the further processing, the structure 1600 is diced so that a structure including the array of nanoholes 640 and at least parts of the one or more conductive materials 692 and 694 can be used to form a thermoelectric leg by doping the substrate material into either p type or n type. In another embodiment, the method as shown in FIGS. 6A-6P can be used to process the substrate 300 as shown in FIG. 3A, the patch 310 as shown in FIG. 3B, and/or the stripe 320 as shown in FIG. 3C.

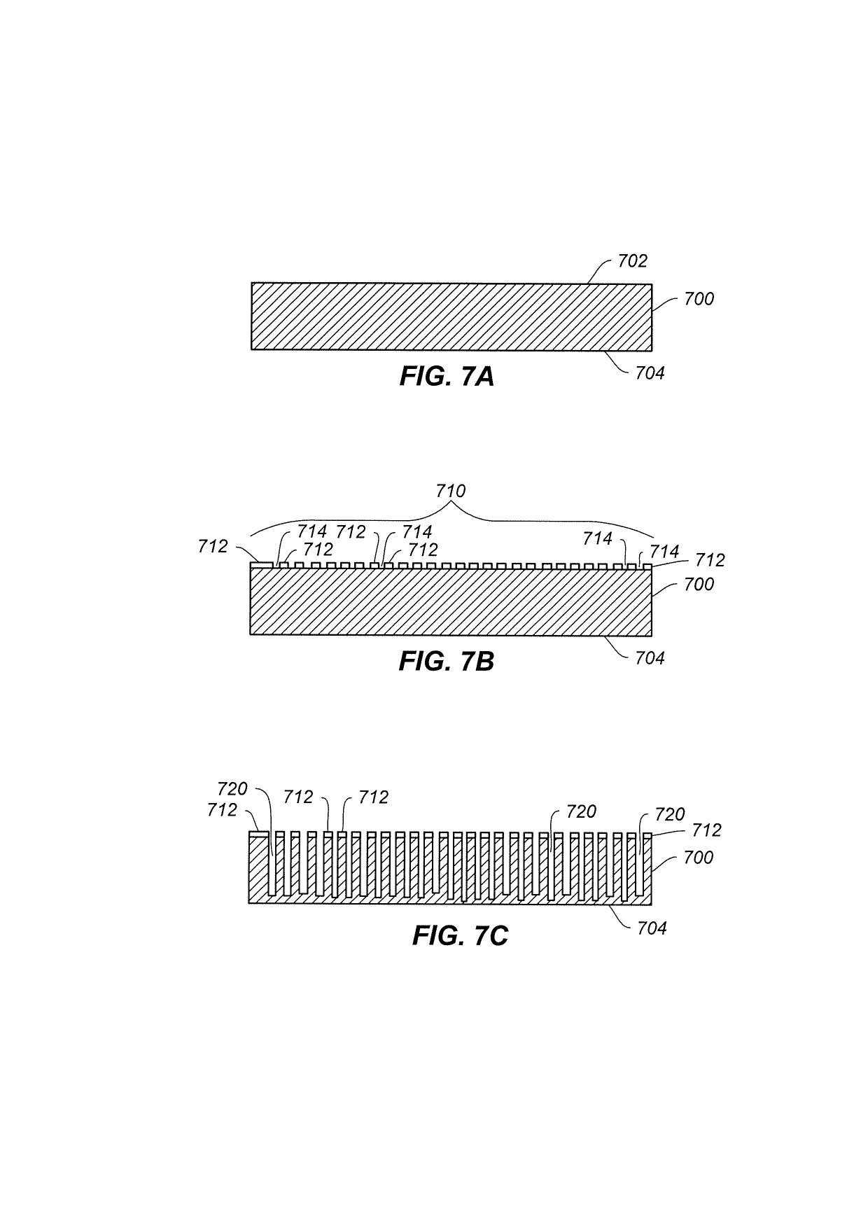

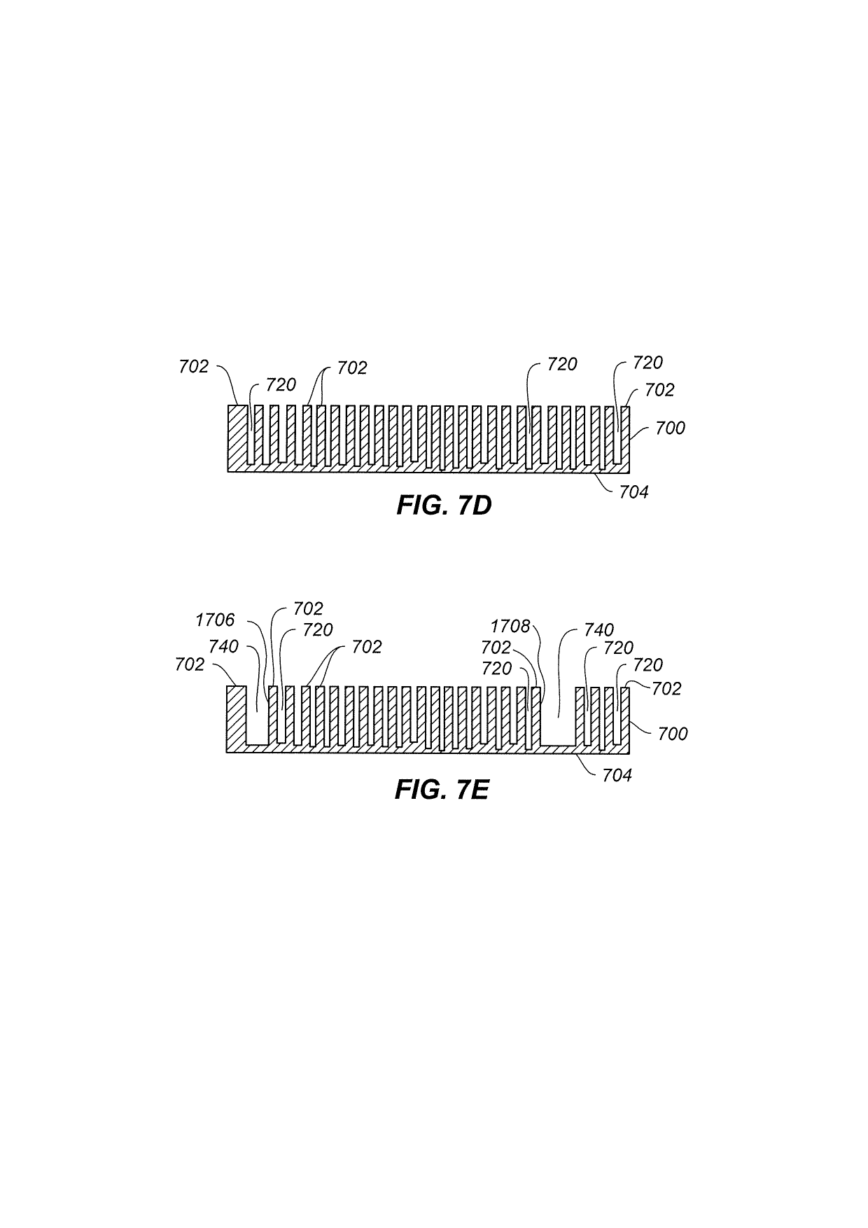

FIGS. 7A-7E are simplified diagrams showing a method for making one or more arrays of nanoholes in a substrate according to yet another embodiment of the present invention. These diagrams are merely examples, which should not unduly limit the scope of the claims. One of ordinary skill in the art would recognize many variations, alternatives, and modifications.

In one embodiment, the method for making one or more arrays of nanoholes in a substrate includes the following sequential processes (a) through (e):
(a) providing a substrate for forming one or more arrays of nanoholes (e.g., as shown in FIG. 7A);
(b) forming a mask on the substrate surface of the substrate (e.g., as shown in FIG. 7B);
(c) forming multiple nanoholes in the substrate (e.g., as shown in FIG. 7C);
(d) removing the mask (e.g., as shown in FIG. 7D); and
(e) re-masking the substrate and then forming multiple trenches in the substrate (e.g., as shown in FIG. 7E);
   The method described above is merely an example, which should not unduly limit the scope of the claims. One of ordinary skill in the art would recognize many variations, alternatives, and modifications. For example, one or more of the above listed processes are skipped. In another example, the above listed processes are performed in a different order. In yet another example, one or more additional processes are added.

As shown in FIG. 7A, a substrate 700 is provided for forming one or more arrays of nanoholes. For example, the substrate 700 includes substrate surfaces 702 and 704, and the substrate surface 704 is located opposite to the substrate surface 702. In another example, the substrate 700 is selected from various types of materials depending on embodiments. In one embodiment, a semiconductor substrate is selected as the substrate 700 for making one or more thermoelectric devices. For example, the substrate 700 is a silicon substrate (e.g., a single-crystal silicon substrate). In another example, the silicon substrate is a silicon wafer without special treatment (e.g., not a silicon-on-insulator wafer). In yet another example, the silicon substrate is uniformly doped into an n-type semiconductor or a p-type semiconductor. In yet another example, the silicon substrate is pattern-doped so that the n-type doping and the p-type doping are performed alternately in alternate patches respectively across the wafer.

As shown in FIG. 7B, a mask 710 is formed on the substrate surface 702 of the substrate 700. In one embodiment, the mask 710 extends to a bulk dimension of about several millimeters to centimeters or greater in the top view. In another embodiment, the mask 710 includes multiple mask islands 712 separated by multiple holes 714. For example, within each hole 414, the substrate surface 702 is exposed. In yet another example, the holes 714 are in nanoscopic scale, and the hole-to-hole separations (e.g., the pitch sizes) are also in nanoscopic scale. According to one embodiment, one or more co-polymer materials including metal particles are used to form the mask 710. According to another embodiment, one or more photoresist materials are used to pattern another inorganic material layer in order to form the mask 710.

As shown in FIG. 7C, multiple nanoholes 720 are formed in the substrate 700. In one embodiment, the nanoholes 720 are formed by applying an etching process (e.g., an anisotropic dry etching process, an anisotropic wet etching process with an etchant solution) through the holes 714. In another embodiment, the nanoholes 720 are substantially vertical to the substrate surface 702, extending into the substrate 700 with corresponding depths. For example, the corresponding depths each exceed 100 μm. In another example, the corresponding depths each are at least 200 μm. In yet another example, the corresponding depths each are at least 400 μm. In yet another example, the corresponding depths each are at least 500 μm. In yet another example, the corresponding depths each are up to the total thickness of the substrate 700. In yet another embodiment, the nanoholes 720 form an array of nanoholes 720. For example, the density of the array of nanoholes 720 has a hole density characterized by separations of the holes 714 (e.g., the pitch sizes). In another example, the average pitch size is about 70 nm. In yet another embodiment, the cross-sectional areas of corresponding nanoholes 720 determine the porosity of the resulting substrate structure as shown in FIG. 7C.

According to one embodiment, a top view of the array of nanoholes 720 as shown in FIG. 7C is depicted in the simplified diagram of FIG. 2, where the nanoholes 210 are the nanoholes 720. According to another embodiment, the mask 710 can be applied over any bulk-like thickness dimension so that one or more arrays of nanoholes 720 can be formed across the surface regions with the same bulk-like thickness dimension.

According to some embodiments, the nanoholes 720 are formed in the substrate 700 by anisotropic wet chemical etching process for an extended period of time. For example, the structure as shown in FIG. 7C is first processed by an etchant solution containing AgNO₃/H₂O₂ with 1% HF in a short time period (e.g., a time period shorter than 30 seconds). As a result, a few silver particles deposit and stay over the exposed substrate surface 702 (e.g., the exposed silicon substrate surface 702). Further, the structure is subject to chemical etching of the substrate 700 (e.g., the silicon substrate 700) using H₂O₂/HF/H₂O/HNO₃ solution while the previously deposited silver particles serve as surfactant to drive the etching reaction with silicon specifically at the bottom of each hole 714. The etching process is extended further to cause the formation of the nanoholes 720. According to certain embodiment, the anisotropic dry etching process is a plasma dry etching process.

According to some embodiments, the anisotropic wet etching process can create roughened and/or porous sidewall surfaces for the nanoholes 720 and therefore reduce the thermal conductivity. According to certain embodiments, the nanoholes 720 are formed by applying an anisotropic etching process with an etchant solution that includes HF, AgNO₃, and H₂O. For example, the molar concentration of HF in the etchant solution varies from 2M to 10M. In another example, the molar concentration of AgNO₃ in the etchant solution varies from 0.001M to 0.5M. In yet another example, other molar concentrations vary depending on the etching parameters desired. In yet another embodiment, KNO₃ is added to the etchant solution. In one example, the KNO₃ is added to the etchant solution after a certain time period of initial etching without KNO₃ in the etchant solution. In another example, KNO₃ is added to the etchant solution all at once. In yet another example, KNO₃ is added to the etchant solution continuously at a predetermined rate. In yet another example, KNO₃ is added to the etchant solution to maintain the proper balance between Ag and Ag+ to control the etching rate, the anisotropy, and/or other etch characteristics. In yet another embodiment, other oxidizing agents other than KNO₃ are added to the etchant solution. In yet another embodiment, the anisotropic etching process of the substrate 700 includes multiple subprocesses. In one example, a first etchant solution including HF, AgNO₃, and H₂O is used for a first time period and then a second etchant solution including HF, H₂O₂, and H₂O is used for a second time period. In another example, a third etchant solution including HF, AgNO₃, and H₂O is used for a third time period and then a fourth etchant solution including HF, Fe(NO₃)₃, and H₂O is used for a fourth time period.

As shown in FIG. 7D, the mask 710 is removed. In one embodiment, the removal of the mask 710 uses chemical treatment and/or mechanical polishing.

As shown in FIG. 7E, the substrate 700 is re-masked and then multiple trenches 740 are formed in the substrate 700. For example, each of the trenches 740 is formed by removing the substrate material between multiple nanoholes and thus combining these multiple nanoholes 720 (e.g., two nanoholes 720, three nanoholes 720). In one embodiment, each of the trenches 740 has a width of about a few 100 microns up to millimeters or greater.

In another embodiment, the trenches 740 have depths that are approximately equal to the corresponding depths of the nanoholes 720. In yet another embodiment, the trenches 740 are used for forming electrical and/or thermal contacts of a nanohole structure (e.g., a bulk nanohole structure including the nanoholes 720 between the trenches 740) associated with the array of nanoholes 720. For example, one of the trenches 740 is used for forming a thermal and electrical contact to a substrate surface 1706 of the substrate 700. In another example, another one of the trenches 740 is used for forming a thermal and electrical contact to a substrate surface 1708 of the substrate 700. According to one embodiment, the substrate surface 1706 extends from the substrate surface 702 towards the substrate surface 704. For example, the substrate surface 1706 is in direct contact with the substrate surface 702 but not with the substrate surface 704. In another example, the substrate surface 1706 is substantially perpendicular to both the substrate surfaces 702 and 704. According to another embodiment, the substrate surface 1708 extends from the substrate surface 702 towards the substrate surface 704. For example, the substrate surface 1708 is in direct contact with the substrate surface 702 but not with the substrate surface 704. In another example, the substrate surface 1708 is substantially perpendicular to both the substrate surfaces 702 and 704. In yet another embodiment, a top view of the array of nanoholes 720 as shown in FIG. 7E is depicted in the simplified diagram of FIG. 2, where the nanoholes 210 are the nanoholes 720.

As discussed above and further emphasized here, FIGS. 7A-7E are merely examples, which should not unduly limit the scope of the claims. One of ordinary skill in the art would recognize many variations, alternatives, and modifications. In one embodiment, the structure as shown in FIG. 7E is further processed to form one or more parts of a thermoelectric device. For example, during the further processing, a barrier layer is formed to cover the trenches (e.g., similar to FIG. 4E), a seed layer is formed to cover the barrier layer in the trenches (e.g., similar to FIG. 4F), one or more conductive materials are formed to cover the seed layer and fill the trenches (e.g., similar to FIG. 4G), and one or more structures with one or more arrays of nanoholes are formed (e.g., similar to FIG. 4H).

In another embodiment, the trenches 740 are formed also to provide patterned patches on the substrate 700 and used for completely dicing out the substrate 700 into a plurality of unit blocks of material. For example, the patch size (e.g., a distance between two trenches 740) can be selected to be in millimeter or centimeter range so that each block of material becomes a nanohole structure, which includes one or more arrays of nanoholes 720.

In another example, such one or more arrays of nanoholes 720 are formed across a bulk lateral dimension (e.g., the patch size) within each patch, and bound by thermal and electrical contacts formed on the sides of the patch (e.g., opposite sides of the patch) that are approximately in parallel to the corresponding depths of the nanoholes 720.

Certain Embodiments provide a bulk nanohole structure including arrays of nanoholes having ultra-long lengths exceeding 100 micrometers formed substantially vertically into a semiconductor substrate. For example, the arrays of ultra-long nanoholes are distributed with a pitch size about 60 nm to 100 nm and an average hole size of about 20 nm to 40 nm. In an embodiment, the arrays of ultra-long nanoholes and a plurality of patterned trenches are formed together by etching from a first patterned mask with porous nanoscopic sized holes. The first patterned mask includes porous nanoscopic sized holes within any of a plurality of patterned patches divided by a set of line patterns across the semiconductor substrate. For example, each patch has bulk dimensions ranging from a few millimeters to 10 centimeters and greater, for the arrays of ultra-long nanoholes formed therein. Along the set of line patterns, at least partially, a contact metal or conductive material can be formed therein. In another example, the semiconductor substrate can be diced along the sets of line patterns, with contact metal filled therein, to form a single block of material or a stripe of material having multiple blocks. In yet another example, the single block of material forms a bulk nanohole structure including arrays of ultra-long nanoholes formed in each patch with two conductive contacts coupled from two sides, based on which a single thermoelectric leg is formed. The stripe of material having multiple blocks are simply multiple blocks without being diced into multiple single blocks and the whole stripe itself can be used to form alternative thermoelectric devices, according to some embodiments.

In another embodiment, a first mask is applied to specifically form the arrays of ultra-long nanoholes using a chemical wet etching technique. The arrays of ultra-long nanoholes are formed substantially vertically into the semiconductor substrate having lengths exceeding hundreds of micrometers and a density characterized by a pitch size of less than 100 nanometers. The first mask is removed and the arrays of ultra-long nanoholes are filled by oxide material. Then a second mask is applied to determine bulk-sized patches and be used to perform another etching process to form a plurality of contact regions along boundaries of each patch. A metal material is deposited to form electric contacts at the plurality of contact regions before a dicing process is applied to transform the bulk-sized patches into multiple bulk nanohole structures with two conductive side contacts coupled to arrays of ultra-long nanoholes therein according to certain embodiments.

In yet another embodiment, bulk nanohole structures include arrays of ultra-long nanoholes formed substantially vertically into bulk semiconductor substrates. The arrays of nanoholes have lengths of several hundred micrometers and a density characterized by a pitch size less than 100 nm. The bulk nanohole structures can be formed into any sized blocks as large as centimeter-range patterns within a silicon wafer. Each block is configured to couple with a pair of contact electrodes from two sides, which are formed directly in the same silicon wafer substantially in parallel to the arrays of nanoholes. For example, the block with the bulk nanohole structures provides a mechanically strong material unit with high electrical conductance but with much lower thermal conductivity than same sized bulk material. In yet another embodiment, certain methods are provided for forming the ultra-long nanoholes, the bulk nanohole structures, based on which various electronic devices including high-performance thermoelectric devices are formed.

According to another embodiment, an array of nanoholes includes a plurality of nanoholes. Each of the plurality of nanoholes corresponds to a first end and a second end, and the first end and the second end are separated by a first distance of at least 100 μm. Each of the plurality of nanoholes corresponds to a cross-sectional area associated with a distance across, and the distance across ranges from 5 nm to 500 nm. Each of the plurality of nanoholes is separated from at least another nanohole selected from the plurality of nanoholes by a semiconductor material associated with a sidewall thickness, and the sidewall thickness ranges from 5 nm to 500 nm. For example, the array of nanoholes is implemented according to at least FIGS. 1A-1D, FIG. 2, FIG. 3B, FIG. 3C, FIGS. 4A-4H, FIG. 5A, FIG. 5B, FIGS. 6A-6P, and/or FIGS. 7A-7E.

According to yet another embodiment, a structure including an array of nanoholes includes a semiconductor substrate with a plurality of nanoholes. The semiconductor substrate includes a first surface, a second surface opposite to the first surface, a third surface extending from the first surface towards the second surface, and a fourth surface extending from the first surface towards the second surface. Each of the plurality of nanoholes corresponds to a first end at the first surface and a second end. Additionally, the structure includes a first thermal and electrical contact material coupled to the third surface, and a second thermal and electrical contact material coupled to the fourth surface. Each of the plurality of nanoholes corresponds to a cross-sectional area associated with a distance across, and the distance across ranges from 5 nm to 500 nm. Each of the plurality of nanoholes is separated from at least another nanohole selected from the plurality of nanoholes by a semiconductor sidewall associated with a sidewall thickness. The semiconductor sidewall is a part of the semiconductor substrate, and the sidewall thickness ranges from 5 nm to 500 nm. For example, the array of nanoholes is implemented according to at least FIGS. 4A-4H, FIG. 5A, FIG. 5B, FIGS. 6A-6P, and/or FIGS. 7A-7E.

According to yet another embodiment, a method for forming an array of nanoholes includes providing a semiconductor substrate including a first surface and forming a mask on the first surface. The mask includes mask regions separated by corresponding mask holes, and portions of the first surface are exposed within the corresponding mask holes. Additionally, the method includes etching the semiconductor substrate through at least the exposed portion of the first surface to form at least nanoholes. Each of the nanoholes corresponds to a first end and a second end, and the first end and the second end are separated by a first distance of at least 100 μm. Each of the nanoholes corresponds to a cross-sectional area associated with a distance across ranging from 5 nm to 500 nm. Each of the nanoholes is separated from at least another of the nanoholes by a semiconductor sidewall associated with a sidewall thickness ranging from 5 nm to 500 nm, and the semiconductor sidewall is a part of the semiconductor substrate. For example, the method is implemented according to at least FIGS. 1A-1D, FIGS. 4A-4H, FIGS. 6A-6P, and/or FIGS. 7A-7E.

According to yet another embodiment, a method for forming a structure including an array of nanoholes includes providing a semiconductor substrate including a first surface and forming a mask on the first surface. The mask includes mask regions separated by corresponding mask holes, and portions of the first surface are exposed within the corresponding mask holes. Additionally, the method includes etching the semiconductor substrate through at least the exposed portion of the first surface to form at least nanoholes. Each of the nanoholes corresponds to a first end at the first surface and a second end. Each of the nanoholes corresponding to a cross-sectional area associated with a distance across ranging from 5 nm to 500 nm. Each of the nanoholes is separated from at least another of the nanoholes by a semiconductor sidewall associated with a sidewall thickness ranging from 5 nm to 500 nm, and the semiconductor sidewall is a part of the semiconductor substrate. Also, the method includes etching the semiconductor substrate to form at least a first trench and a second trench, forming a first thermal and electrical contact within the first trench with the semiconductor substrate, and forming a second thermal and electrical contact within the second trench with the semiconductor substrate. For example, the method is implemented according to at least FIGS. 4A-4H, FIGS. 6A-6P, and/or FIGS. 7A-7E.

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. An array of nanoholes, the array comprising:
a plurality of nanoholes, each of the plurality of nanoholes corresponding to a first end and a second end, the first end and the second end being separated by a first distance of at least 100 μm;
wherein:
each of the plurality of nanoholes corresponds to a cross-sectional area associated with a distance across, the distance across ranging from 5 nm to 500 nm; and
each of the plurality of nanoholes is separated from at least another nanohole selected from the plurality of nanoholes by a semiconductor material associated with a sidewall thickness, the sidewall thickness ranging from 5 nm to 500 nm.

2. The array of claim 1 wherein:
the distance across ranges from 20 nm to 40 nm; and
the sidewall thickness ranges from 40 nm to 60 nm.

3. The array of nanoholes of claim 1 wherein all nanoholes of the plurality of nanoholes are substantially parallel to each other.

4. The array of nanoholes of claim 3 wherein each of the plurality of nanoholes corresponds to the first end at a first surface and is substantially perpendicular to the first surface.

5. The array of nanoholes of claim 1 wherein the cross-sectional area is substantially uniform along a longitudinal direction for each of the plurality of nanoholes.

6. The array of nanoholes of claim 1 wherein the semiconductor material is silicon.

7. The array of nanoholes of claim 1 wherein the plurality of nanoholes is a part of a thermoelectric device.

8. The array of nanoholes of claim 1 wherein the first distance is at least 200 μm.

9. The array of nanoholes of claim 8 wherein the first distance is at least 400 μm.

10. The array of nanoholes of claim 9 wherein the first distance is at least 500 μm.

11. A structure including an array of nanoholes, the structure comprising:
a semiconductor substrate with a plurality of nanoholes, the semiconductor substrate including a first surface, a second surface opposite to the first surface, a third surface extending from the first surface towards the second surface, and a fourth surface extending from the first surface towards the second surface, each of the plurality of nanoholes corresponding to a first end at the first surface and a second end;
a first thermal and electrical contact material coupled to the third surface; and
a second thermal and electrical contact material coupled to the fourth surface; wherein:
each of the plurality of nanoholes corresponds to a cross-sectional area associated with a distance across, the distance across ranging from 5 nm to 500 nm; and
each of the plurality of nanoholes is separated from at least another nanohole selected from the plurality of nanoholes by a semiconductor sidewall associated with a sidewall thickness, the semiconductor sidewall being a part of the semiconductor substrate, the sidewall thickness ranging from 5 nm to 500 nm.

12. The array of claim 11 wherein:
the distance across ranges from 20 nm to 40 nm; and
the sidewall thickness ranges from 40 nm to 60 nm.

13. The structure of claim 11 wherein each of the plurality of nanoholes corresponds to the second end at the second surface.

14. The structure of claim 11 wherein each of the plurality of nanoholes corresponds to the second end within the semiconductor substrate.

15. The structure of claim 11 wherein:
the third surface is in direct contact with both the first surface and the second surface; and
the fourth surface is in direct contact with both the first surface and the second surface.

16. The structure of claim 11 wherein:
the third surface is substantially perpendicular to both the first surface and the second surface; and
the fourth surface is substantially perpendicular to both the first surface and the second surface.

17. The structure of claim 11 wherein each of the plurality of nanoholes is substantially perpendicular to the first surface.

18. The structure of claim 11 wherein the cross-sectional area is substantially uniform along a longitudinal direction for each of the plurality of nanoholes.

19. The structure of claim 18 wherein the longitudinal direction is substantially perpendicular to the first surface.

20. The structure of claim 11 wherein the semiconductor substrate includes silicon.

21. The structure of claim 11 is a part of a thermoelectric device.

22. A method for forming an array of nanoholes, the method comprising:
providing a semiconductor substrate including a first surface;
forming a mask on the first surface, the mask including mask regions separated by corresponding mask holes, portions of the first surface being exposed within the corresponding mask holes; and
etching the semiconductor substrate through at least the exposed portion of the first surface to form at least nanoholes, each of the nanoholes corresponding to a first end and a second end, the first end and the second end being separated by a first distance of at least 100 μm, each of the nanoholes corresponding to a cross-sectional area associated with a distance across ranging from 5 nm to 500 nm, each of the nanoholes being separated from at least another of the nanoholes by a semiconductor sidewall associated with a sidewall thickness ranging from 5 nm to 500 nm, the semiconductor sidewall being a part of the semiconductor substrate.

23. The array of claim 22 wherein:
the distance across ranges from 20 nm to 40 nm; and
the sidewall thickness ranges from 40 nm to 60 nm.

24. The method of claim 22 wherein the process for forming a mask on the first surface includes using a photolithography process.

25. The method of claim 22 wherein the process for etching the semiconductor substrate includes a dry etch process.

26. The method of claim 22 wherein the process for etching the semiconductor substrate includes a wet etch process using an etchant solution with one or more metal materials.

27. The method of claim 26 wherein the one or more metal materials include silver.

28. The method of claim 22 wherein the semiconductor material is silicon.

29. A method for forming a structure including an array of nanoholes, the method comprising:
providing a semiconductor substrate including a first surface;
forming a mask on the first surface, the mask including mask regions separated by corresponding mask holes, portions of the first surface being exposed within the corresponding mask holes; and
etching the semiconductor substrate through at least the exposed portion of the first surface to form at least nanoholes, each of the nanoholes corresponding to a first end at the first surface and a second end, each of the nanoholes corresponding to a cross-sectional area associated with a distance across ranging from 5 nm to 500 nm, each of the nanoholes being separated from at least another of the nanoholes by a semiconductor sidewall associated with a sidewall thickness ranging from 5 nm to 500 nm, the semiconductor sidewall being a part of the semiconductor substrate;
etching the semiconductor substrate to form at least a first trench and a second trench;
forming a first thermal and electrical contact within the first trench with the semiconductor substrate; and
forming a second thermal and electrical contact within the second trench with the semiconductor substrate.

30. The array of claim 29 wherein:
the distance across ranges from 20 nm to 40 nm; and
the sidewall thickness ranges from 40 nm to 60 nm.

31. The method of claim 29 wherein the process for etching the semiconductor substrate through at least the exposed portion of the first surface to form at least nanoholes and the process for etching the semiconductor substrate to form at least a first trench and a second trench both use the same mask.

32. The method of claim 29 wherein the process for etching the semiconductor substrate to form at least a first trench and a second trench is performed after the process for etching the semiconductor substrate through at least the exposed portion of the first surface to form at least nanoholes.
